(19) United States
(12) Patent Application Publication
(10) Pub. No.: US 2026/0327488 A1
(43) Pub. Date: Oct. 22, 2026

(54) METHOD FOR MANUFACTURING QUANTUM DOT, THE QUANTUM DOT, AND ELECTRONIC APPARATUS INCLUDING THE QUANTUM DOT

(71) Applicant: Samsung Display Co., Ltd., Yongin-si (KR)

(72) Inventors: Hongrae KIM, Yongin-si (KR); SUNGJAE KIM, Yongin-si (KR); Youngsik KIM, Yongin-si (KR); SEUNG-WON PARK, Yongin-si (KR); Bitna YOON, Yongin-si (KR); JUNEHYUK JUNG, Yongin-si (KR); TAEKJOON LEE, Yongin-si (KR)

(21) Appl. No.: 19/427,916

(22) Filed: Dec. 19, 2025

(30) Foreign Application Priority Data
Apr. 14, 2025 (KR) 10-2025-0048355

(51) Int. Cl. C09K 11/62; C09K 113/00; H10K 50/115

(52) U.S. Cl. CPC C09K 11/621; H10K 50/115; C09K 2113/00

(57) ABSTRACT

A method for manufacturing a quantum dot, a quantum dot and an electronic apparatus including the quantum dot are provided. The method includes forming a core containing copper, indium, gallium, and sulfur, and forming a shell around (e.g., surrounding) the core, wherein the forming of the core includes preparing a first mixture including a first copper precursor, a first indium precursor, and a first gallium precursor, adding a first sulfur precursor to the first mixture to form a second mixture, and adding a metal material to the second mixture to form a third mixture, wherein the metal material includes at least one of a second copper precursor, a second indium precursor, a second gallium precursor, or a second sulfur precursor.

### CROSS-REFERENCE TO RELATED APPLICATIONS

The present application claims priority to and the benefit of Korean Patent Application No. 10-2025-0048355, filed on Apr. 14, 2025, the entire content of which is incorporated herein by reference.

### BACKGROUND

### 1. Field

Embodiments of the present disclosure relate to a method for manufacturing a quantum dot including providing a metal material, the quantum dot manufactured by the method, and an electronic apparatus including the quantum dot.

### 2. Description of the Related Art

A quantum dot, which is a semiconductor nanocrystal, may have different energy band gaps by varying the size and composition of the nanocrystal, and may be to emit light in various wavelengths. A quantum-dot light-emitting element, in which quantum dots are utilized as a light-emitting material, is being developed with a focus on enhancing color reproducibility. For example, a quantum dot including a core and a shell may have reduced color purity and material stability after the formation of the shell, and thus research into improving this feature is desirable.

The above information disclosed in this Background section is intended to enhance understanding of the background of the disclosure and may contain information that does not constitute prior art.

### SUMMARY

Aspects of one or more embodiments of the present disclosure are directed toward a method for manufacturing a quantum dot which exhibits excellent or suitable processibility.

Aspects of one or more embodiments of the present disclosure are directed toward a quantum dot which exhibits excellent or suitable efficiency, and an electronic apparatus including the same.

Aspects of one or more embodiments of the present disclosure are directed toward a method for manufacturing, a quantum dot, and an electronic apparatus including the quantum dot having a narrow full width at half-maximum (FWHM), and a low tail value, and/or high quantum yield, thus providing a quantum dot with suitable or excellent light-emitting efficiency.

Additional aspects will be set forth in part in the description which follows and, in part, will be apparent from the description, or may be learned by practice of the presented embodiments of the disclosure.

One or more embodiments of the present disclosure provide a method for manufacturing a quantum dot including forming a core containing copper, indium, gallium, and sulfur, and forming a shell around (e.g., surrounding) the core, wherein the forming of the core includes preparing a first mixture containing a first copper precursor, a first indium precursor, and a first gallium precursor, adding a first sulfur precursor to the first mixture to form a second mixture, and adding a metal material to the second mixture to form a third mixture, and the metal material includes at least one of a second copper precursor, a second indium precursor, a second gallium precursor, or a second sulfur precursor.

In one or more embodiments, the method for manufacturing the quantum dot may further include heating the first mixture at a first temperature after the preparing of the first mixture.

In one or more embodiments, the method for manufacturing the quantum dot may further include heating the second mixture from a first temperature to a second temperature after the forming of the second mixture.

In one or more embodiments, the forming of the third mixture may be performed during the heating of the second mixture from the first temperature to the second temperature.

In one or more embodiments, in the forming of the third mixture, an atomic percentage of the indium may decrease with the heating time, and an atomic percentage of the gallium atom may increase with the heating time.

In one or more embodiments, the metal material may include the second copper precursor, the second indium precursor, the second gallium precursor, and the second sulfur precursor.

In one or more embodiments, the forming of the third mixture may include the adding of the metal material n times, and n above may be an integer of 1 or greater and 7 or less (e.g., 1 to 7).

In one or more embodiments, n above may be an integer of 2 or greater and 5 or less (e.g., 2 to 5).

In one or more embodiments, the adding of the metal material n times may define a first cycle, and the first cycle may be about 30 minutes or greater and about 2 hours or less (e.g., about 30 minutes to about 2 hours).

In one or more embodiments, the first and second copper precursors may each independently includes copper iodide, the first and second indium precursors may each independently includes at least one of indium iodide, indium chloride, or indium acetate, the first and second gallium precursors may each independently includes at least one of gallium iodide, gallium chloride, or gallium acetate, and the first and second sulfur precursors may each independently includes at least one of sulfur-oleylamine, octanethiol, or dodecanethiol.

In one or more embodiments of the present disclosure, a quantum dot includes a core containing copper, indium, gallium, and sulfur, and a shell around (e.g., surrounding) the core, the core includes a first portion containing a center point, and a second portion defined between the first portion and the shell, an atomic percentage of the indium included in the first portion is greater than an atomic percentage of the indium included in the second portion, and an atomic percentage of the gallium included in the first portion is less than an atomic percentage of the gallium included in the second portion.

In one or more embodiments, the quantum dot may have a full width of half maximum of about 60 nm or less.

In one or more embodiments, a central emission wavelength of the quantum dot may be in a wavelength range of about 500 nm to about 650 nm (e.g., about 500 nm to about 650 nm).

In one or more embodiments, the copper may have an amount of about 5 wt % or greater and about 20 wt % or less (e.g., about 5 wt % to about 20 wt %), the indium may have an amount of about 10 wt % or greater and about 30 wt % or less (e.g., about 10 wt % to about 30 wt %), the gallium may have an amount of about 10 wt % or greater and about 50 wt % or less (e.g., about 10 wt % to about 50 wt %), and the sulfur may have an amount of about 40 wt % or greater and about 60 wt % or less (e.g., about 40 wt % to about 60 wt %) based on 100 wt % of a total mass of the core.

In one or more embodiments, the shell may include ZnS.

In one or more embodiments, the shell may include a first layer around (e.g., surrounding) the core, and a second layer around (e.g., surrounding) the first layer, and the first layer may include ZnS.

In one or more embodiments, the second layer may include at least one of ZnSe, ZnS, ZnTe, ZnO, ZnMg, ZnMgSe, ZnMgS, ZnMgAl, GaSe, GaTe, GaP, GaAs, GaSb, InAs, InSb, AlP, AlAs, AlSb, MnS, MnSe, MgS, or MgSe.

In one or more embodiments, a thickness of the second layer may be larger than a thickness of the first layer.

In one or more embodiments of the present disclosure, an electronic apparatus includes a display module containing a light-emitting element configured to emit source light, and an optical layer arranged on the display module, and configured to transmit the source light or convert a wavelength of the source light, the light-emitting element or the optical layer includes a quantum dot, the quantum dot includes a core containing copper, indium, gallium, and sulfur, and a shell around (e.g., surrounding) the core, the core includes a first portion containing a center point, and a second portion defined between the first portion and the shell, a weight percentage of the indium included in the first portion is greater than a weight percentage of the indium included in the second portion, and a weight percentage of the gallium included in the first portion is less than a weight percentage of the gallium included in the second portion.

In one or more embodiments, the electronic apparatus may further include a window member arranged on the optical layer, and a housing arranged under the display module and coupled to the window member to accommodate the display module and the optical layer.

For example, in one or more embodiments, the quantum dot manufactured by the disclosed method includes a core having a radial gradient in indium and gallium content, and a shell including zinc sulfide or a bilayer structure. The resulting quantum dot may exhibit a narrow full width at half maximum (FWHM), a central emission wavelength in the visible range, and a high quantum yield. These properties make the quantum dot suitable for integration into electronic apparatuses and/or display devices, where it may be used in light-emitting elements or optical layers to enhance color purity and energy efficiency.

### BRIEF DESCRIPTION OF THE FIGURES

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a perspective view of an electronic apparatus according to one or more embodiments of the present disclosure;

FIG. 2 is a block diagram of an electronic apparatus according to one or more embodiments of the present disclosure;

FIG. 3 shows schematic perspective views of various electronic apparatuses according to embodiments of the present disclosure;

FIG. 4 is an exploded perspective view of an electronic apparatus according to one or more embodiments of the present disclosure;

FIG. 5 is a cross-sectional view taken along the line I-I′ of FIG. 4, according to one or more embodiments of the present disclosure;

FIG. 6 is a plan view of a portion of a display module of an electronic apparatus according to one or more embodiments of the present disclosure;

FIG. 7 is a cross-sectional view taken along the line II-II′ of FIG. 6, according to one or more embodiments of the present disclosure;

FIG. 8A is a cross-sectional view of a light-emitting element according to one or more embodiments of the present disclosure;

FIG. 8B is a cross-sectional view of a light-emitting element according to one or more embodiments of the present disclosure;

FIG. 9 is a drawing schematically illustrating a quantum dot according to one or more embodiments of the present disclosure;

FIG. 10A is a flow chart of a method for manufacturing a quantum dot according to one or more embodiments of the present disclosure;

FIG. 10B is a flow chart illustrating a part forming a core of the method for manufacturing a quantum dot, according to one or more embodiments of the present disclosure;

FIG. 11A is a line graph showing changes in core composition over time, according to one or more embodiments of the present disclosure;

FIG. 11B is a graph showing changes in core composition over time, according to a comparative example;

FIG. 12A is a graph showing a luminescence intensity according to wavelength for a core and a quantum dot, according to one or more embodiments of the present disclosure; and

FIG. 12B is a graph showing a luminescence intensity according to wavelength for a core and a quantum dot according to a comparative example.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on,” “connected to,” or “coupled to” another element, it can be directly on, connected to, or coupled to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present.

Unless otherwise noted, like reference numerals denote like elements throughout the attached drawings and the written description, and thus, duplicative descriptions thereof may not be provided. In the drawings, the thickness, ratio, and size of the elements may be exaggerated for effectively describing the technical contents. In the drawings, the relative sizes (e.g., including lengths, widths and thicknesses) of elements, layers, and regions may be exaggerated for clarity.

As used herein, the term “and/or” includes any and all combinations of one or more of the associated listed items.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a,” “an” and “the” are intended to include the plural forms as well, unless the context clearly indicates otherwise.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be further understood that the terms “comprises,” “comprising,” “includes,” “including,” “have,” “having,” “contain,” and “containing,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having,” “contain/containing,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

In the specification, when a range states, “about A or greater and about B or less,” it may refer to a range of “about A to about B.”

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

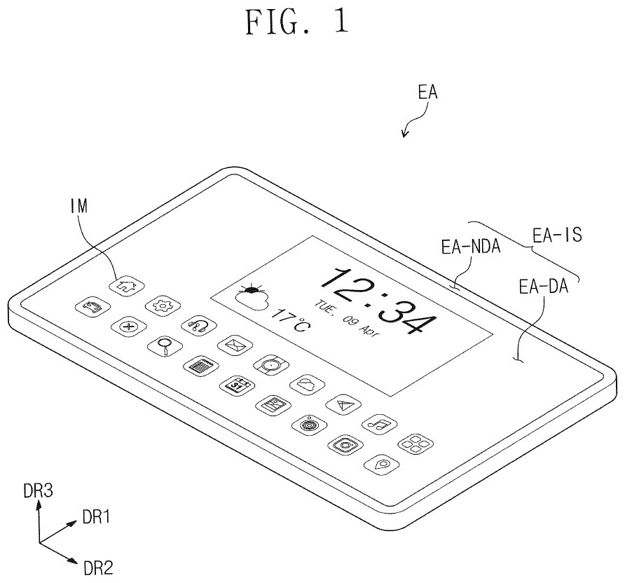

Hereinafter, embodiments of the present disclosure will be described with reference to the accompanying drawings. FIG. 1 is a perspective view of an electronic apparatus according to one or more embodiments of the present disclosure.

As shown in FIG. 1, an electronic apparatus EA according to one or more embodiments may be activated in response to electrical signals. For example, the electronic apparatus EA may be a personal computer, a laptop computer, a personal digital assistant, a game console, a portable electronic device, a television, a monitor, an outdoor billboard, a car navigation, or a wearable device, but the present disclosure is not limited thereto. FIG. 1 illustrates that the electronic apparatus EA is a portable electronic device as an example.

The electronic apparatus EA may provide an image IM to a user through a display surface EA-IS. The display surface EA-IS may be parallel to a plane defined by a first directional axis DR1 and a second directional axis DR2. The electronic apparatus EA may display the image IM toward a direction of a third directional axis DR3. The image IM may include a still image as well as a dynamic image. FIG. 1 illustrates the electronic apparatus EA including a flat display surface EA-IS, but the present disclosure is not limited thereto. For example, the electronic apparatus EA may also include a curved display surface or a three-dimensional display surface. The three-dimensional display surface may also include a plurality of display regions indicating different directions.

In this specification, directions indicated by the first to third directional axes DR1, DR2, and DR3 may be relative concepts, and may be changed to other directions. In addition, the directions indicated by the first to third directional axes DR1, DR2, and DR3 may be described as first to third directions, and may be denoted as the same reference numerals or symbols throughout.

In this specification, the first directional axis DR1 and the second directional axis DR2 may cross each other, and the third directional axis DR3 may be a normal direction of the plane defined by the first directional axis DR1 and the second directional axis DR2. A thickness direction of the electronic apparatus EA may be a direction parallel to the third directional axis DR3. The thickness direction of the electronic apparatus EA may be denoted as the same reference numeral or symbol as the third directional axis DR3. A front surface (or upper surface) and a rear surface (or lower surface) may be opposed to each other in the third directional axis DR3, and the normal direction of each of the front surface (or upper surface) and the rear surface (or lower surface) may be parallel to the third directional axis DR3. The front surface (or upper surface) refers to a surface adjacent to the display surface EA-IS, and the rear surface (or lower surface) refers to a surface spaced and/or apart (e.g., spaced apart or separated) from the display surface EA-IS. An upper side refers to a side closer to the display surface EA-IS, and a lower side refers to a side away from the display surface EA-IS.

In this specification, a cross-section refers to a surface parallel to the thickness direction DR3. “In a plane” or “in a plan view” refers to a surface normal (e.g., perpendicular) to the thickness direction DR3, and parallel to the plane defined by the first directional axis DR1 and the second directional axis DR2.

In this specification, one component overlapping another component refers to overlapping on a plane (e.g., in a plan view). In addition, one component overlapping another component is not limited to the case where the one component and the other component have the same area and same shape, and also includes the case of having different areas and/or different shapes.

The electronic apparatus EA may detect an external input applied from the outside. The external input may include one or more suitable types (kinds) of inputs provided from the outside of the electronic apparatus EA. For example, the external input may include not only an external input applied by contact of a part of a user's body, such as a hand, but also an external input applied in proximity to, or adjacent at a distance to, the electronic apparatus EA (for example, hovering). In one or more embodiments, the external input may include one or more suitable forms such as power, pressure, temperature, and light.

The display surface EA-IS may include a display region EA-DA and a non-display region EA-NDA. The electronic apparatus EA may display the image IM through the display region EA-DA.

The display region EA-DA may be a region activated in response to electrical signals. The display region EA-DA may be a region on which the image IM is displayed, and a region capable of detecting one or more suitable types (kinds) of external inputs.

The display region EA-DA may include a flat surface defined by the first directional axis DR1 and the second directional axis DR2. Unlike what is illustrated in the drawing, the display region EA-DA may include a curved surface bent from at least one side of the flat surface defined by the first directional axis DR1 and the second directional axis DR2. For example, the display region EA-DA may further include curved surfaces bent from at least two sides of the flat surface defined by the first directional axis DR1 and the second directional axis DR2, for example, four curved surfaces respectively bent from four sides of the flat surface.

In one or more embodiments, the electronic apparatus EA may be flexible. The meaning of being “flexible” may indicate bendable characteristics, and may include everything from a structure of being completely foldable to a structure bendable to several nanometers. In one or more embodiments, the electronic apparatus EA may be a rigid apparatus. In one or more embodiments, the electronic apparatus EA may also be a foldable apparatus.

The non-display region EA-NDA may have a color. The non-display region EA-NDA may be a region adjacent to the display region EA-DA. The non-display region EA-NDA may be around (e.g., surround) the display region EA-DA. Accordingly, the shape of the display region EA-DA may be substantially defined by the non-display region EA-NDA. However, FIG. 1 illustrates an example, and the non-display region EA-NDA may also be arranged adjacent to only one side of the display region EA-DA, and may also not be provided. The display region EA-DA may be provided in one or more suitable shapes, and is not limited to any one embodiment.

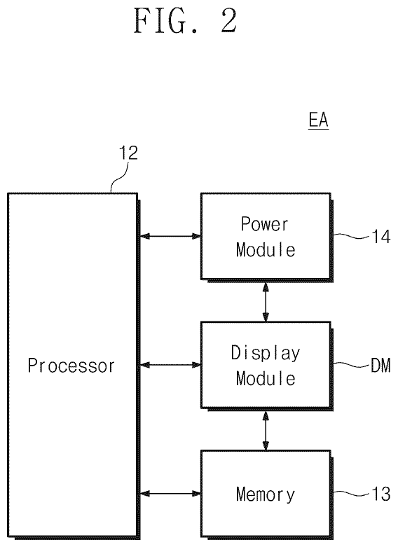

FIG. 2 is a block diagram of an electronic apparatus according to one or more embodiments of the present disclosure. Referring to FIG. 2, an electronic apparatus EA according to one or more embodiments may include a display module DM, a processor 12, a memory 13, and a power module 14.

The processor 12 may include at least one of a central processing unit (CPU), an application processor (AP), a graphic processing unit (GPU), a communication processor (CP), an image signal processor (ISP), or a controller. The power module 14 may include a power supply module such as a power adapter or a battery device, and a power-converting module that converts power supplied by the power supply module, and generates power for operation of the electronic apparatus EA.

In the memory 13, data information for operation of the processor 12 or the display module DM may be stored. When the processor 12 runs an application stored in the memory 13, image data signals and/or input control signals may be transmitted to the display module DM, and the display module DM may process the received signals to output image information through a display screen.

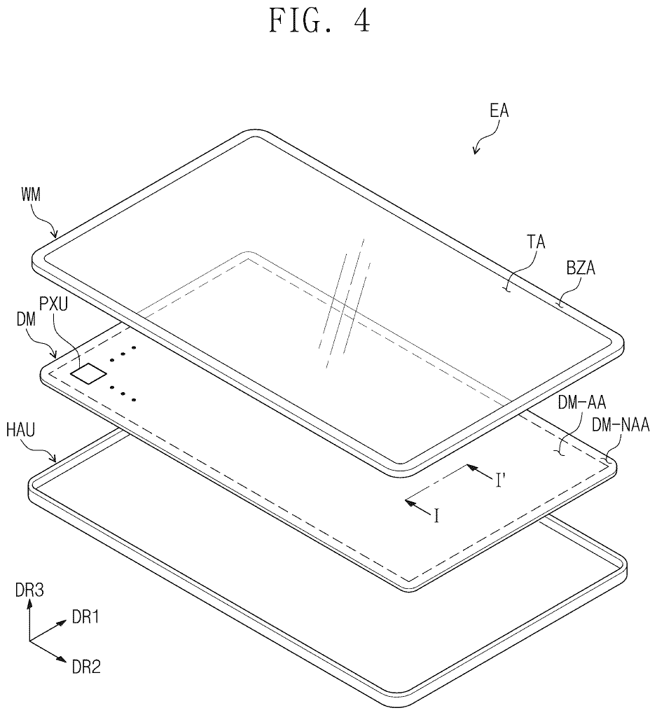

At least one of the components of the electronic apparatus EA may be included in the display module DM (see, e.g., FIG. 4) according to one or more embodiments. In addition, some individual modules included in one functional module, among the components of the electronic apparatus EA, may be included in a display device and others may also be provided separately from the display device. For example, the display device may include the display module DM, and the processor 12, the memory 13, and the power module 14 may be provided in the form of a device other than the display device in the electronic apparatus EA.

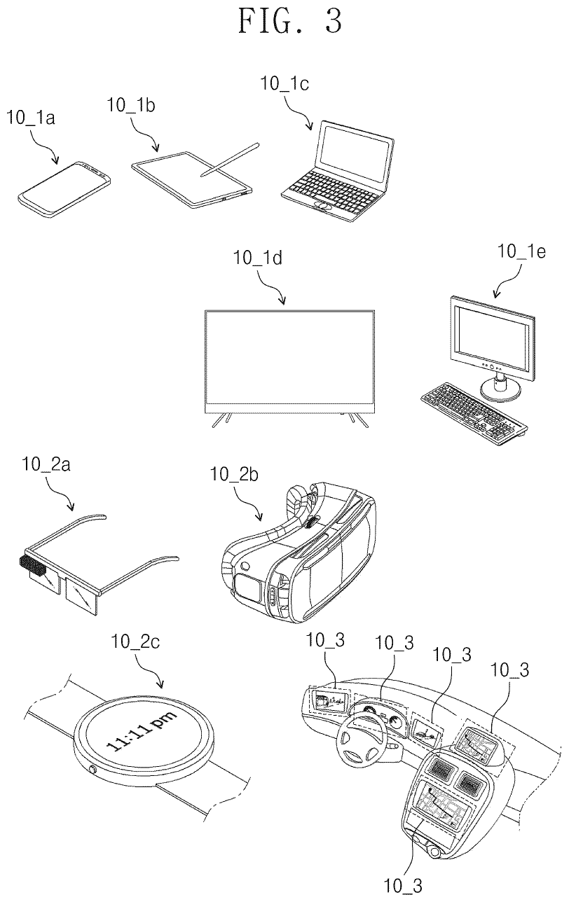

FIG. 3 shows schematic perspective views of various electronic apparatuses according to embodiments of the present disclosure. Referring to FIG. 3, the electronic apparatus including the display module DM (see, e.g., FIG. 2) according to one or more embodiments may not only include an electronic apparatus for displaying images, such as a smartphone 10_1a, a tablet PC 10_1b, a laptop computer 10_1c, a TV 10_1d, and a desktop monitor 10_1e, but may also include a wearable electronic apparatus including a display device, such as smart glasses 10_2a, a head-mounted display 10_2b, and a smart watch 10_2c, an electronic apparatus for a vehicle 10_3 including a display device such as a car dashboard, a center fascia, a center information display (CID) arranged on the dashboard, and a room mirror display, and/or the like.

FIG. 4 is an exploded perspective view of an electronic apparatus according to one or more embodiments of the present disclosure. Referring to FIG. 4, an electronic apparatus EA may include a display module DM. In one or more embodiments, the electronic apparatus EA may further include a window member WM and a housing HAU.

The window member WM may be arranged on the display module DM. The window member WM may cover the entire outer side of the electronic apparatus EA. The window member WM may include a transmission region TA and a bezel region BZA. A front surface of the window member WM, including the transmission region TA and the bezel region BZA, may correspond to a front surface of the electronic apparatus EA. The transmission region TA may correspond to the display region EA-DA of the electronic apparatus EA illustrated in FIG. 1, and the bezel region BZA may correspond to the non-display region EA-NDA of the electronic apparatus EA illustrated in FIG. 1.

The transmission region TA may be an optically transparent region. The bezel region BZA may be a region which is relatively low in light transmittance, compared to the transmission region TA. The bezel region BZA may have a color. The bezel region BZA may be adjacent to the transmission region TA, and may be around (e.g., surround) the transmission region TA. The bezel region BZA may define the shape of the transmission region TA. However, the present disclosure is not limited thereto, and the bezel region BZA may also be arranged adjacent only to one side of the transmission region TA, and a portion of the bezel region BZA may also not be provided.

The housing HAU may include a material that is relatively high in rigidity. For example, the housing HAU may include a frame and/or a plate made of glass, plastic, or metal. The frame and/or the plate may be provided in plurality. The housing HAU may provide an accommodating space. The display module DM may be accommodated in the accommodating space, and may thus be protected from external impact.

The display module DM may be activated in response to electrical signals, and provide the image IM (see, e.g., FIG. 1). By the activation, the display module DM may display the image or video IM (see, e.g., FIG. 1) on the display region EA-DA (see, e.g., FIG. 1) of the electronic apparatus EA. An active region DM-AA and a peripheral region DM-NAA may be defined in the display module DM.

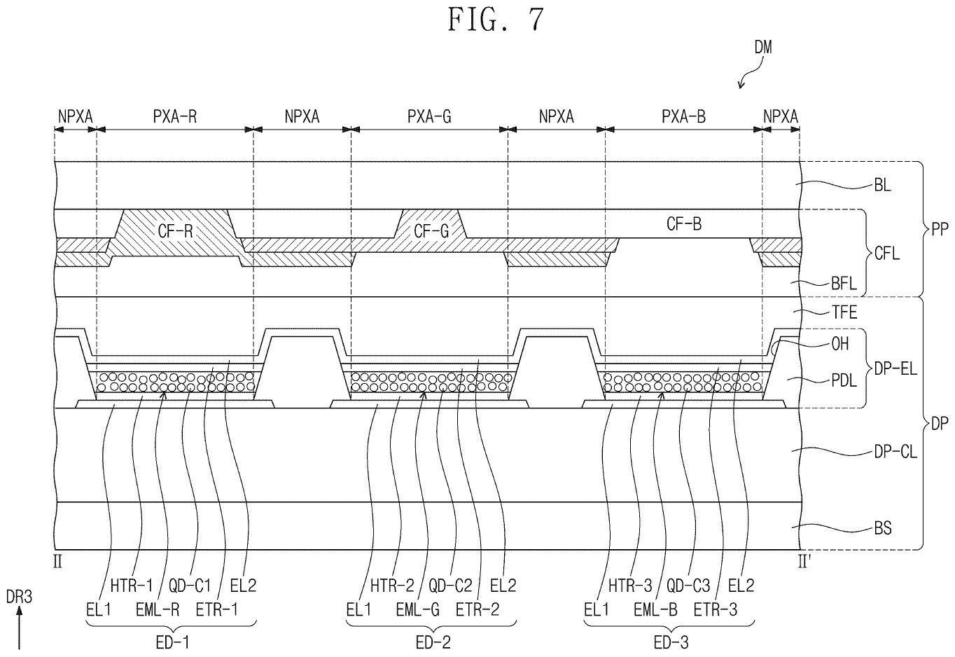

The active region DM-AA may be a region activated in response to electrical signals. A unit pixel PXU may be arranged in the active region DM-AA. The pixel UPX may include a transistor and a light-emitting element ED-1, ED-2, and ED-3 (see, e.g., FIG. 7). The peripheral region DM-NAA may be a region positioned adjacent to at least one side of the active region DM-AA. A circuit, wiring, and/or the like for driving the active region DM-AA may be arranged in the peripheral region DM-NAA.

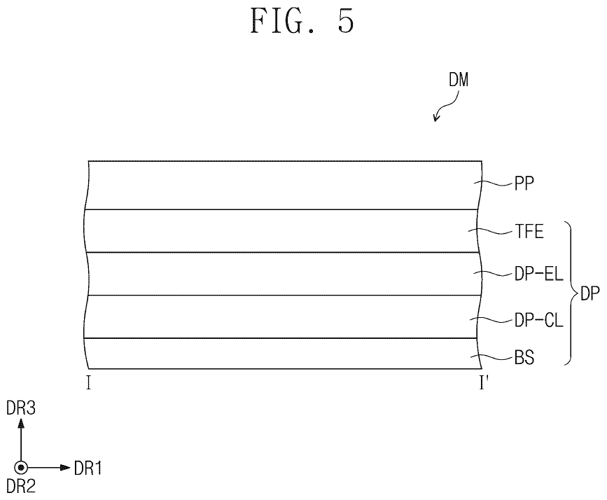

FIG. 5 is a cross-sectional view illustrating a portion taken along the line I-I′ of FIG. 4, according to one or more embodiments of the present disclosure. FIG. 5 is a cross-sectional view of a display module according to one or more embodiments.

The display module DM may include a display panel DP and an optical layer PP arranged on the display panel DP. The display panel DP may include a base layer BS, a circuit layer DP-CL arranged on the base layer BS, a display element layer DP-EL arranged on the circuit layer DP-CL, and an encapsulation layer TFE arranged on the display element layer DP-EL.

The display panel DP may be a component that substantially generates images. The display panel DP may be an emission-type (kind) display panel. For example, the display panel DP may be a quantum-dot light-emitting display panel including a quantum-dot light-emitting element.

The base layer BS may be a member that provides a base surface where the circuit layer DP-CL is arranged. The base layer BS may be a rigid substrate, or a flexible substrate capable of bending, folding, rolling, and/or the like. The base layer BS may be a glass substrate, a metal substrate, a polymer substrate, and/or the like. However, the present disclosure is not limited thereto, and the base layer BS may be an inorganic layer, an organic layer, or a composite material layer.

The circuit layer DP-CL may be arranged on the base layer BS. The circuit layer DP-CL may include an insulation layer, a semiconductor pattern, a conductive pattern, a signal line, and/or the like. An insulation layer, a semiconductor layer, and a conductive layer may be formed on the base layer BS through coating, deposition, and/or the like, and then the insulation layer, the semiconductor layer, and the conductive layer may be selectively patterned through multiple cycles of photolithography processes. After this, the semiconductor pattern, the conductive pattern, and the signal line included in the circuit layer DP-CL may be formed.

The display element layer DP-EL may be arranged on the circuit layer DP-CL. The display element layer DP-EL may include a pixel-defining film PDL (see, e.g., FIG. 7) and first to third light-emitting elements ED-1, ED-2, and ED-3 (see, e.g., FIG. 7) to be described in more detail later. For example, the display element layer DP-EL may include an organic light-emitting material, an inorganic light-emitting material, an organic-inorganic light-emitting material, quantum dots, and/or quantum rods. For example, the display element layer DP-EL may include a micro-LED or a nano-LED. In one or more embodiments, the display element layer DP-EL may include quantum dots.

The encapsulation layer TFE may protect the display element layer DP-EL from moisture, oxygen, and foreign substances, such as dust particles. The encapsulation layer TFE may include at least one inorganic layer. The encapsulation layer TFE may include a structure in which an inorganic layer, an organic layer, and an inorganic layer are stacked in sequence.

The optical layer PP may be arranged on the display panel DP and may control of the reflection of external light on the display panel DP. The optical layer PP may include, for example, a polarization layer, or include a color filter layer. In one or more embodiments, the optical layer PP may also not be provided.

In one or more embodiments, the display module DM may further include an input-sensing layer arranged between the display panel DP and the optical layer PP. The input-sensing layer may detect an external input and convert the external input into an input signal, and may provide the input signal to the display panel DP. For example, the input-sensing layer may be a touch-sensing layer that detects touch. The input-sensing layer may recognize a direct touch of a user, an indirect touch of a user, a direct touch of an object, an indirect touch of an object, and/or the like.

The input-sensing layer may detect at least one of a position of a touch or a strength (pressure) of the touch applied from the outside. In one or more embodiments, the input-sensing layer may have one or more suitable structures or may include one or more suitable materials. However, the present disclosure is not limited to any one embodiment. For example, the input-sensing layer may detect the external input in a capacitance manner. The display panel DP may receive input signals from the input-sensing layer, and may generate an image corresponding to the input signals.

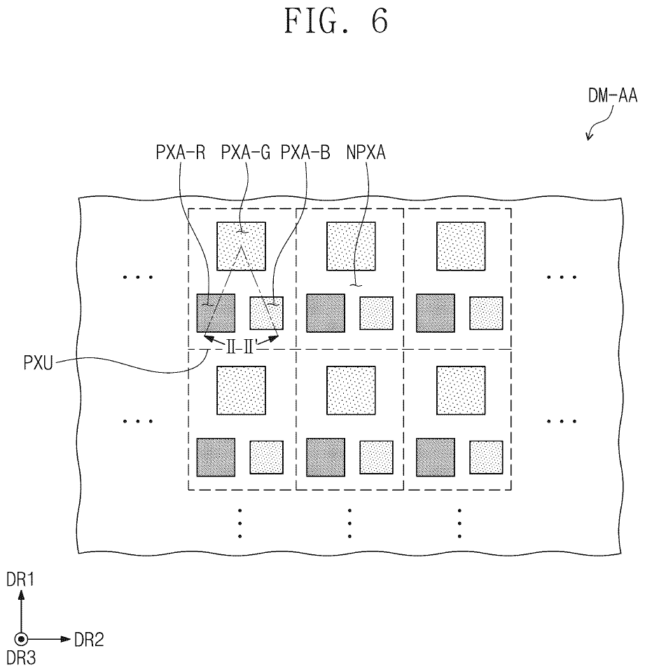

FIG. 6 is a plan view schematically illustrating an active region DM-AA of a display module DM, according to one or more embodiments of the present disclosure. FIG. 6 illustrates a portion of the active region DM-AA showing several unit pixels UPX each including three pixel regions PXA-R, PXA-G, and PXA-B and a light-blocking region NPXA, as an example. A unit pixel PXU may include the first to third pixel regions PXA-R, PXA-G, and PXA-B and the light-blocking region NPXA. The unit pixel PXU may be arranged repeatedly in the entire active region DM-AA illustrated in FIG. 4.

The light-blocking region NPXA may be arranged around the first to third pixel regions PXA-R, PXA-G, and PXA-B. The light-blocking region NPXA may set boundaries between the first to third pixel regions PXA-R, PXA-G, and PXA-B. The light-blocking region NPXA may be around (e.g., surround) the first to third pixel regions PXA-R, PXA-G, and PXA-B. In the light-blocking region NPXA, a structure that prevents color mixing between the first to third pixel regions PXA-R, PXA-G, and PXA-B, for example, a pixel-defining film PDL (see, e.g., FIG. 7), and/or the like, may be arranged.

The pixel regions PXA-R, PXA-G, and PXA-B may be regions where light generated from the first to third light-emitting elements ED-1, ED-2, and ED-3 are emitted, respectively. FIG. 6 illustrates that the first to third pixel regions PXA-R, PXA-G, and PXA-B have the same shape on a plane (e.g., in a plan view), and have different areas on a plane (e.g., in a plan view), but the present disclosure is not limited thereto. At least two pixel regions among the first to third pixel regions PXA-R, PXA-G, and PXA-B may have the same area. The areas of the first to third pixel regions PXA-R, PXA-G, and PXA-B may be set according to the color of light to be emitted. The pixel region that emits light of blue color, among primary colors, may have the smallest area. The area may refer to an area on a plane (e.g., in a plan view).

FIG. 6 illustrates that each of the first to third pixel regions PXA-R, PXA-G, and PXA-B has a quadrilateral shape on a plane (e.g., in a plan view). In one or more embodiments, the first to third pixel regions PXA-R, PXA-G, and PXA-B may each have another polygonal shape, such as a diamond or pentagon shape. In one or more embodiments, the first to third pixel regions PXA-R, PXA-G, and PXA-B may each have a quadrilateral shape with rounded corners. The first to third pixel regions PXA-R, PXA-G, and PXA-B may also have different shapes on a plane (e.g., in a plan view).

FIG. 6 illustrates that the second pixel regions PXA-G are arranged on a first row, and the first pixel regions PXA-R and the third pixel regions PXA-B are arranged on a second row. However, this is an example, and the arrangement of the first to third pixel regions PXA-R, PXA-G, and PXA-B may be changed in one or more suitable ways. For example, the first to third pixel regions PXA-R, PXA-G, and PXA-B may be arranged on the same row.

One among the first to third pixel regions PXA-R, PXA-G, and PXA-B may be to emit first light, another may be to emit second light different from the first light, and yet another may be to emit third light different from the first light and the second light. For example, the first pixel region PXA-R may be to emit red color light, the second pixel region PXA-G may be to emit green color light, and the third pixel region PXA-B may be to emit blue color light. The first pixel region PXA-R may be referred to as a red pixel region, the second pixel region PXA-G may be referred to as a green pixel region, and the third pixel region PXA-B may be referred to as a blue pixel region.

FIG. 7 is a cross-sectional view illustrating a portion taken along the line II-II′ of FIG. 6. FIG. 7 is a cross-sectional view illustrating the configuration of a display module DM according to one or more embodiments of the present disclosure.

Referring to FIG. 7, a base layer BS may have a single layer or multiple layers. For example, the base layer BS may include a three-layer structure of a polymer resin layer, an adhesion layer, and a polymer resin layer. For example, the polymer resin layer may include a polyimide-based resin. In one or more embodiments, the polymer resin layer may include at least one of an acrylate-based resin, a methacrylate-based resin, a polyisoprene-based resin, a vinyl-based resin, an epoxy-based resin, a urethane-based resin, a cellulose-based resin, siloxane-based resin, a polyamide-based resin, or a perylene-based resin. In this specification, “~~”-based resin refers to including the functional group of “~~ ”. For example, the polyimide-based resin refers to including a polyimide functional group.

The circuit layer DP-CL may include an insulation layer, a semiconductor layer, a conductive layer, a signal line, and/or the like. The circuit layer DP-CL may include a plurality of transistors. The transistors may each include a control electrode, an input electrode, and an output electrode. For example, the circuit layer DP-CL may include a switching transistor and a driving transistor for driving a light-emitting element ED-1, ED-2, and ED-3 of the display element layer DP-EL.

The display element layer DP-EL may include first to third light-emitting elements ED-1, ED-2, and ED-3 and a pixel-defining film PDL. The pixel-defining film PDL may have an opening OH (e.g., a plurality of openings OH) defined therein.

The pixel-defining film PDL may define the pixel regions PXA-R, PXA-G, and PXA-B. The pixel regions PXA-R, PXA-G, and PXA-B and the light-blocking region NPXA may be divided by the pixel-defining film PDL.

The pixel-defining film PDL may include a polymer resin. For example, the pixel-defining film PDL may include a polyacrylate-based resin or a polyimide-based resin. In one or more embodiments, the pixel-defining film PDL may further include an inorganic material in addition to the polymer resin. The pixel-defining film PDL may include a light-absorbing material, or include a black pigment and/or black dye. The pixel-defining film PDL including the black pigment and/or black dye may provide a black pixel-defining film. When the pixel-defining film PDL is formed, carbon black, and/or the like, may be used as the black pigment and/or black dye, but the present disclosure is not limited thereto.

In one or more embodiments, the pixel-defining film PDL may include an inorganic material. For example, the pixel-defining film PDL may include an inorganic material such as silicon nitride (SiNₓ), silicon oxide (SiOₓ), and/or silicon oxynitride (SiOₓN_{y}).

The light-emitting elements ED-1, ED-2, and ED-3 may each include a first electrode EL1, an emission layer EML-R, EML-G, and EML-B arranged on the first electrode EL1, a second electrode EL2 arranged on the emission layer EML-R, EML-G, and EML-B, a hole transport region HTR-1, HTR-2, and HTR-3 arranged between the first electrode EL1 and the second electrode EL2, and an electron transport region ETR-1, ETR-2, and ETR-3 arranged between the first electrode EL1 and the second electrode EL2. The electron transport region ETR-1, ETR-2, and ETR-3 may be spaced and/or apart (e.g., spaced apart or separated) from the hole transport region HTR-1, HTR-2, and HTR-3 with the emission layer EML-R, EML-G, and EML-B therebetween.

The light-emitting elements ED-1, ED-2, and ED-3 may each include the first electrode EL1, the hole transport region HTR-1, HTR-2, and HTR-3 arranged on the first electrode EL1, the emission layer EML-R, EML-G, and EML-B arranged on the hole transport region HTR-1, HTR-2, and HTR-3, the electron transport region ETR-1, ETR-2, and ETR-3 arranged on the emission layer EML-R, EML-G, and EML-B, and the second electrode EL2 arranged on the electron transport region ETR-1, ETR-2, and ETR-3.

At least a portion of the first electrode EL1 may be exposed by an opening OH of the pixel-defining film PDL (e.g., at least a portion of each of the first electrodes EL1 may be exposed in each of the plurality of openings OH). The first electrode EL1 may have conductivity (e.g., may be a conductor). The first electrode EL1 may include a metal material, a metal alloy, or a conductive compound. The first electrode EL1 may be a cathode or an anode. However, the present disclosure is not limited thereto. In one or more embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected therefrom, a (e.g., any suitable) mixture of two or more selected therefrom, or an oxide thereof.

In embodiments in which the first electrode EL1 is a transmissive electrode, the first electrode EL1 may include a transparent metal oxide, for example, indium tin oxide (ITO), indium zinc oxide (IZO), zinc oxide (ZnO), indium tin zinc oxide (ITZO), and/or the like. In embodiments in which the first electrode EL1 is a transflective electrode or reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound thereof and/or a (e.g., any suitable) mixture thereof (for example, a mixture of Ag and Mg). In one or more embodiments, the first electrode EL1 may have a multi-layer structure including a reflective film or transflective film including the above-mentioned materials, and a transparent conductive film including indium tin oxide (ITO), indium zinc oxide (IZO), zinc oxide (ZnO), indium tin zinc oxide (ITZO), and/or the like. For example, the first electrode EL1 may have a three-layer structure of ITO/Ag/ITO, but the present disclosure is not limited thereto. In one or more embodiments, the first electrode EL1 may include the above-described metal materials, a (e.g., any suitable) combination of at least two metal materials selected from among the above-described metal materials, an oxide of the above-described metal materials, and/or the like. However, the present disclosure is not limited thereto. The first electrode EL1 may have a thickness of about 700 Å to about 10000 Å. For example, the thickness of the first electrode EL1 may be about 1000 Å to about 3000 Å.

The second electrode EL2 may be a common electrode. The second electrode EL2 may be an anode or a cathode, but the present disclosure is not limited thereto. For example, in embodiments in which the first electrode EL1 is an anode, the second electrode EL2 may be a cathode, and in embodiments in which the first electrode EL1 is a cathode, the second electrode EL2 may be an anode. The second electrode EL2 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture (e.g., any suitable) of two or more selected therefrom, or an oxide thereof.

The second electrode EL2 may be a transmissive electrode, a transflective electrode, or a reflective electrode. In embodiments in which the second electrode EL2 is the transmissive electrode, the second electrode EL2 may include a transparent metal oxide, for example, indium tin oxide (ITO), indium zinc oxide (IZO), zinc oxide (ZnO), indium tin zinc oxide (ITZO), and/or the like.

In embodiments in which the second electrode EL2 is the transflective electrode or reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound and/or a (e.g., any suitable) mixture thereof (for example, AgMg, AgYb, or MgYb). In one or more embodiments, the second electrode EL2 may have a multi-layer structure including a reflective film or transflective film including the above-mentioned materials, and a transparent conductive film including indium tin oxide (ITO), indium zinc oxide (IZO), zinc oxide (ZnO), indium tin zinc oxide (ITZO), and/or the like. For example, the second electrode EL2 may include the above-described metal materials, a (e.g., any suitable) combination of at least two metal materials selected from among the above-described metal materials, an oxide of the above-described metal materials, and/or the like.

In one or more embodiments, the second electrode EL2 may be a connected to an auxiliary electrode. If the second electrode EL2 is connected to the auxiliary electrode, resistance of the second electrode EL2 may be reduced.

The emission layers EML-R, EML-G, and EML-B may be arranged between the first electrode EL1 and the second electrode EL2. The first light-emitting element ED-1 may include a first emission layer EML-R, the second light-emitting element ED-2 may include a second emission layer EML-G, and the third light-emitting element ED-3 may include a third emission layer EML-B. The first emission layer EML-R may include a first quantum dot QD-C1. The second emission layer EML-G may include a second quantum dot QD-C2. The third emission layer EML-B may include a third quantum dot QD-C3.

The quantum dots QD-C1, QD-C2, and QD-C3 respectively included in the emission layers EML-R, EML-G, and EML-B may be stacked to form a layer. FIG. 7 illustrates that the quantum dots QD-C1, QD-C2, and QD-C3 having a circular cross-section are arranged to form about 2 layers as an example, but the present disclosure is not limited thereto. For example, the arrangement of the quantum dots QD-C1, QD-C2, and QD-C3 may vary according to the thickness of the emission layer EML-R, EML-G, and EML-B, the shape of the quantum dot QD-C1, QD-C2, and QD-C3 included in the emission layer EML-R, EML-G, and EML-B, and the average diameter of the quantum dots QD-C1, QD-C2, and QD-C3. For example, in the emission layers EML-R, EML-G, and EML-B, the quantum dots QD-C1, QD-C2, and QD-C3 may be arranged adjacent to each other to form one layer, or arranged to form multiple layers such as two layers, three layers, and/or the like.

The first quantum dot QD-C1 of the first light-emitting element ED-1 may be to emit red color light. The second quantum dot QD-C2 of the second light-emitting element ED-2 may be to emit green color light. The third quantum dot QD-C3 of the third light-emitting element ED-3 may be to emit blue color light. For example, the quantum dots QD-C1, QD-C2, and QD-C3 may each include a core and a shell around (e.g., surrounding) the core. The cores of the quantum dots QD-C1, QD-C2, and QD-C3 may include different materials. In one or more embodiments, any two cores among the cores of the quantum dots QD-C1, QD-C2, and QD-C3 may include the same materials, and the other one core may include a different material.

FIG. 7 illustrates that the first to third quantum dots QD-C1, QD-C2, and QD-C3 may have similar diameters, but the present disclosure is not limited thereto. The first to third quantum dots QD-C1, QD-C2, and QD-C3 may have different diameters. For example, the third quantum dot QD-C3 of the third light-emitting element ED-3 that emits light in a relatively short wavelength range may have a smaller average diameter than those of the first quantum dot QD-C1 of the first light-emitting element ED-1 and the second quantum dot QD-C2 of the second light-emitting element ED-2 that emit light in a relatively long wavelength range. The average diameter refers to an arithmetic average value of the particle diameters of a plurality of quantum dots. The particle diameter of the quantum dot may be an average value of the width of the quantum dot particle on cross-section.

In the present disclosure, when quantum dots are spherical, “diameter” indicates an average quantum dot diameter, and when the quantum dots are non-spherical, the “diameter” indicates a major axis length or an average major axis length. The diameter (or size) of the quantum dots may be measured utilizing a scanning electron microscope or a particle size analyzer. As the particle size analyzer, for example, HORIBA, LA-950 laser particle size analyzer, may be utilized. When the size of the quantum dots is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The hole transport regions HTR-1, HTR-2, and HTR-3 of the first to third light-emitting elements ED-1, ED-2, and ED-3 may be arranged separately in an opening OH. Alternatively, in one or more embodiments, the hole transport regions HTR-1, HTR-2, and HTR-3 of the first to third light-emitting elements ED-1, ED-2, and ED-3 may also be provided as common layers. The hole transport regions HTR-1, HTR-2, and HTR-3 provided as common layers may overlap the pixel regions PXA-R, PXA-G, and PXA-B and the light-blocking region NPXA. The first light-emitting element ED-1 may include a first hole transport region HTR-1, the second light-emitting element ED-2 may include a second hole transport region HTR-2, and the third light-emitting element ED-3 may include a third hole transport region HTR-3.

The first to third hole transport regions HTR-1, HTR-2, and HTR-3 may each have a single layer including a single material, a single layer including a plurality of different materials, or a multi-layer structure including a plurality of layers including a plurality of different materials. The first to third hole transport regions HTR-1, HTR-2, and HTR-3 may each have a thickness of, for example, about 50 Å to about 15,000 Å. The thickness of each of the first to third hole transport regions HTR-1, HTR-2, and HTR-3 may be about 100 Å to about 10000 Å, and for example, about 100 Å to about 5000 Å.

The first to third hole transport regions HTR-1, HTR-2, and HTR-3 may each include a generally available and/or generally utilized hole injection material and/or a generally available and/or generally utilized hole transport material. For example, the first to third hole transport regions HTR-1, HTR-2, and HTR-3 may each include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecyl benzene sulfonic acid (PANI/DBSA), polyaniline/camphor sulfonic acid (PANI/CSA), polyaniline/poly(4-styrene sulfonate) (PANI/PSS), N,N′-di(naphthalene-1-yl)-N,N′-diphenyl-benzidine (NPB), polyether ketone including triphenylamine (TPAPEK), 4-isopropyl-4′-methyldiphenyliodonium [tetrakis(pentafluorophenyl) borate], dipyrazino[2,3-f: 2′,3′-h]quinoxaline-2,3,6,7,10,11-hexacarbonitrile (HATCN), and/or the like.

In one or more embodiments, the first to third hole transport region HTR-1, HTR-2, and HTR-3 may include a carbazole-based derivative such as N-phenyl carbazole and/or polyvinyl carbazole, a fluorene-based derivative, a triphenylamine-based derivative such as N,N′-bis(3-methylphenyl)-N, N′-diphenyl-[1,1′-biphenyl]-4,4′-diamine (TPD) and 4,4′,4″-tris(N-carbazolyl)triphenylamine (TCTA), N,N′-di(naphthalene-1-yl)-N, N′-diphenyl-benzidine (NPB), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 9-(4-tert-butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), or 1,3-bis(1,8-dimethyl-9H-carbazol-9-yl)benzene (mDCP).

The electron transport regions ETR-1, ETR-2, and ETR-3 of the first to third light-emitting elements ED-1, ED-2, and ED-3 may be arranged separately in the openings OH. Alternatively, in one or more embodiments, the electron transport regions ETR-1, ETR-2, and ETR-3 of the first to third light-emitting elements ED-1, ED-2, and ED-3 may also be provided as common layers. The electron transport regions ETR-1, ETR-2, and ETR-3 provided as common layers may overlap the pixel regions PXA-R, PXA-G, and PXA-B and the light-blocking region NPXA. The first light-emitting element ED-1 may include a first electron transport region ETR-1, the second light-emitting element ED-2 may include a second electron transport region ETR-2, and the third light-emitting element ED-3 may include a third electron transport region ETR-3.

The first to third electron transport regions ETR-1, ETR-2, and ETR-3 may each have a single layer including a single material, a single layer including a plurality of different materials, or a multi-layer structure including a plurality of layers including a plurality of different materials. The first to third electron transport regions ETR-1, ETR-2, and ETR-3 may each have a thickness of, for example, about 1000 Å to about 1500 Å.

The first to third electron transport regions ETR-1, ETR-2, and ETR-3 may further include a generally available and/or generally utilized electron injection material and/or a generally available and/or generally utilized electron transport material. For example, the first to third electron transport regions ETR-1, ETR-2, and ETR-3 may include an anthracene compound. In one or more embodiments, the first to third electron transport regions ETR-1, ETR-2, ETR-3 may include, for example, tris(8-hydroxyquinolinato)aluminum (Alq₃), 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzoimidazol-1-yl)phenyl)-9, 10-dinaphthylanthracene, 1,3,5-tri (1-phenyl-1H-benzo[d] imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq₂), 9,10-di(naphthalene-2-yl) anthracene (ADN), 1,3-bis[3,5-di(pyridin-3-yl)phenyl]benzene (BmPyPhB), and/or a (e.g., any suitable) mixture thereof. In one or more embodiments, the first to third electron transport regions ETR-1, ETR-2, and ETR-3 may include 2,9-dimethyl-4,7-diphenyl-1,10-phenanthroline (BCP), diphenyl(4-(triphenylsilyl)phenyl)phosphine oxide (TSPO1), 4,7-diphenyl-1,10-phenanthroline (Bphen), and/or the like.

The encapsulation layer TFE may include at least one inorganic film (hereinafter, inorganic encapsulation film). In one or more embodiments, the encapsulation layer TFE may include at least one organic film (hereinafter, organic encapsulation film) and at least one inorganic encapsulation film.

The inorganic encapsulation film may protect the display element layer DP-EL from moisture/oxygen, and the organic encapsulation film may protect the display element layer DP-EL from foreign substances, such as dust particles. The inorganic encapsulation film may include silicon nitride, silicon oxynitride, silicon oxide, titanium oxide, aluminum oxide, and/or the like, but the present disclosure is not limited particularly thereto. The organic encapsulation film may include an acrylate-based compound, an epoxy-based compound, and/or the like. The organic encapsulation film may include an organic material capable of photopolymerization, and the present disclosure is not limited particularly thereto.

The optical layer PP may include a base substrate BL and a color filter layer CFL. The base substrate BL may be a member that provides a base surface on which the color filter layer CFL is arranged. The base substrate BL may be a glass substrate, a metal substrate, a plastic substrate, and/or the like. However, the present disclosure is not limited thereto, and the base substrate BL may be an inorganic layer, an organic layer, or a composite material layer.

The color filter layer CFL may include first to third filters CF—R, CF-G, and CF—B. The first to third filters CF—R, CF-G, and CF—B may be arranged corresponding to the first to third light-emitting elements ED-1, ED-2, and ED-3, respectively. For example, the first filter CF—R may be a red color filter, the second filter CF-G may be a green color filter, and the third filter CF—B may be a blue color filter. The first to third filters CF—R, CF-G, and CF—B may be arranged corresponding to the first to third light-emitting regions PXA-R, PXA-G, and PXA-B, respectively.

The first to third filters CF—R, CF-G, and CF—B may each include a polymer photosensitive resin, and a pigment and/or dye. The first filter CF—R may include a red pigment and/or red dye, the second filter CF-G may include a green pigment and/or green dye, and the third filter CF—B may include a blue pigment and/or blue dye. However, the present disclosure is not limited thereto, and the third filter CF—B may not include (e.g., may exclude) a pigment or dye. The third filter CF—B may include a polymer photosensitive resin, and may not include (e.g., may exclude) a pigment and/or dye. The third filter CF—B may be transparent. The third filter CF—B may include a transparent photosensitive resin.

The color filter layer CFL may further include a buffer layer BFL. For example, the buffer layer BFL may be a protection layer that protects the first to third filters CF—R, CF-G, and CF—B. The buffer layer BFL may be arranged between the encapsulation layer TFE and the first to third filters CF—R, CF-G, and CF—B. The buffer layer BFL may be an inorganic material layer including at least one inorganic material of silicon nitride, silicon oxide, or silicon oxynitride. The buffer layer BFL may include a single layer or multiple layers.

In one or more embodiments, the first filter CF—R and the second filter CF-G may be yellow filters. The first filter CF—R and the second filter CF-G may not be separated from each other and may be provided as one body.

In one or more embodiments, the color filter layer CFL may further include a light-blocking part. The light-blocking part may be a black matrix. The light-blocking part may include an organic light-blocking material or an inorganic light-blocking material containing a black pigment and/or black dye. The light-blocking part may prevent or reduce a light-leak phenomenon, and may set boundaries between the filters CF—R, CF-G, and CF—B that are adjacent to each other.

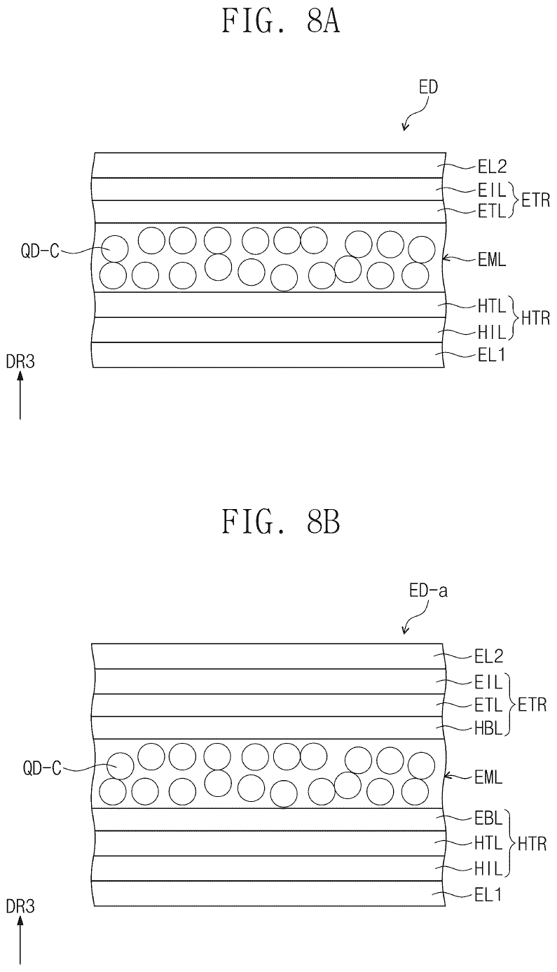

FIGS. 8A and 8B are cross-sectional views each illustrating a light-emitting element ED, ED-a according to one or more embodiments of the present disclosure. Referring to FIGS. 8A and 8B, the light-emitting elements ED and ED-a may each include a first electrode EL1, a hole transport region HTR on the first electrode EL1, an emission layer EML arranged on the hole transport region HTR, an electron transport region ETR arranged on the emission layer EML, and a second electrode EL2 arranged on the electron transport region ETR. The emission layer EML may include a quantum dot QD-C according to one or more embodiments. The quantum dot QD-C according to one or more embodiments will be described in more detail later.

Features of either of the light-emitting elements ED and ED-a described with reference to FIGS. 8A and 8B may be equally applied to any of the first to third light-emitting elements ED-1, ED-2, and ED-3 illustrated in FIG. 7.

Referring to FIGS. 8A and 8B, the light-emitting elements ED and ED-a may each include a first electrode EL1, a hole transport region HTR, a emission layer EML, an electron transport region ETR, and a second electrode EL2 stacked in sequence. The hole transport region HTR may include a hole injection layer HIL and a hole transport layer HTL arranged on the hole injection layer HIL. The electron transport region ETR may include an electron transport layer ETL and an electron injection layer EIL arranged on the electron transport layer ETL.

In the light-emitting element ED-a illustrated in FIG. 8B, the hole transport region HTR may further include an electron-blocking layer EBL arranged on the hole transport layer HTL. The electron transport region ETR may further include a hole-blocking layer HBL arranged between the emission layer EML and the electron transport layer ETL.

In one or more embodiments, the electron injection layer EIL and/or the electron transport layer ETL may not be provided. In one or more embodiments, the hole injection layer HIL and/or the hole transport layer HTL may not be provided.

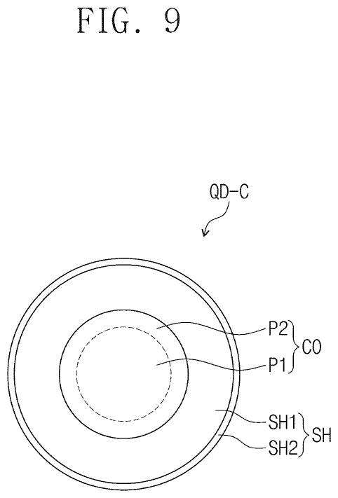

FIG. 9 is a drawing schematically illustrating a quantum dot according to one or more embodiments of the present disclosure. The description on the quantum dot QD-C according to one or more embodiments may be equally applied to any of the above-described first to third quantum dots QD-C1, QD-C2, and QD-C3. For example, at least one of the first or second quantum dot QD-C1 or QD-C2 may be the quantum dot QD-C according to one or more embodiments. In one or more embodiments, the quantum dot QD-C may refer to a crystal of a semiconductor compound.

In one or more embodiments, the quantum dot QD-C may include a core CO, and a shell SH around (e.g., surrounding) the core CO.

The quantum dot QD-C may have a central emission wavelength in a wavelength range of about 500 nm to about 650 nm. The central emission wavelength may refer to a wavelength value at the point of maximum luminescence intensity in an emission spectrum. The quantum dot QD-C according to one or more embodiments may have a full width of half maximum of about 60 nm or less. For example, the quantum dot QD-C according to one or more embodiments may have a full width of half maximum of about 50 nm or less. The quantum dot QD-C according to one or more embodiments having a full width of half maximum of about 50 nm or less may be to emit light with high color purity. The quantum dot QD-C according to one or more embodiments may have a quantum yield of about 85% or greater. The quantum dot QD-C according to one or more embodiments with a quantum yield of about 85% or greater may exhibit excellent or suitable light-emitting efficiency.

In one or more embodiments, the core CO includes a first portion P1 and a second portion P2. The first portion P1 may refer to a portion including a center point, and the second portion P2 may refer to another portion defined between the shell SH and the first portion P1. For example, the core CO may have a spherical shape, and the center point of the core CO may refer to the center point of the sphere. The core CO may have a diameter of about 2 nm or greater and about 10 nm or less (e.g., about 2 nm to about 10 nm).

The core CO may include a multicomponent compound containing copper (Cu), indium (In), gallium (Ga), and sulfur(S). Hereinafter, “the multicomponent compound containing Cu, In, Ga, and S” refers to a “CIGS compound”. In one or more embodiments, copper may have an amount of about 5 wt % or greater and about 20 wt % or less, indium may have an amount of about 10 wt % or greater and about 30 wt % or less, gallium may have an amount of about 10 wt % or greater and about 50 wt % or less, and sulfur may have an amount of about 40 wt % or greater and about 60 wt % or less on the basis of 100 wt % of a total mass of the core CO. For example, the copper may have an amount of about 10 wt % or greater and about 15 wt % or less, the indium may have an amount of about 10 wt % or greater and about 20 wt % or less, the gallium may have an amount of about 15 wt % or greater and about 25 wt % or less, and the sulfur may have an amount of about 50 wt % or greater and about 60 wt % or less.

In the core CO containing the CIGS compound, an atomic percentage of the indium included in the first portion P1 may be greater than an atomic percentage of the indium included in the second portion P2, and an atomic percentage of the gallium included in the first portion P1 may be less than an atomic percentage of the gallium included in the second portion P2. In the core CO including the CIGS compound, the atomic percentage of the indium included in the first portion P1 may be greater than the atomic percentage of the gallium included in the first portion P1. In one or more embodiments, the atomic percentage of the indium included in the second portion P2 may be less than the atomic percentage of the gallium included in the second portion P2. The atomic percentage of the indium may increase from the shell SH to the center point of the core CO, the atomic percentage of the gallium may increase from the center point of the core CO to the shell SH. Because the quantum dot QD-C is manufactured in a method for manufacturing a quantum dot according to one or more embodiments, to be described in more detail later, the core CO may have a relative concentration gradient for the indium element and gallium element.

In the core CO containing the CIGS compound, copper may have an amount of about 5 mass percent (wt %) or greater and about 20 mass percent or less, indium may have an amount of about 10 mass percent or greater and about 30 mass percent or less, gallium may have an amount of about 10 mass percent or greater and about 50 mass percent or less, and sulfur may have an amount of about 40 mass percent or greater and about 50 mass percent or less on the basis of 100 mass percent of the total mass of the core CO. As used herein, “mass percent” refers to weight percent (wt %).

The core CO may have an absorption wavelength of about 350 nm or greater and about 530 nm or less. The core CO containing the CIGS compound may have a high absorption rate for light of about 350 nm or greater and about 530 nm or less. The core CO may be to absorb blue color light of about 350 nm or greater and about 530 nm or less to emit green color light or red color light. By adjusting the size of the core CO, the amount ratio of indium atoms in the core CO, the amount ratio of gallium atoms in the core CO, the thickness of the shell SH, and/or the like, the wavelength of light emitted from the quantum dot QD-C may be changed.

The shell SH may effectively passivate a surface of the core CO for defects present on the surface to thereby increase luminance efficiency, and increase stability of the quantum dot QD-C. The shell SH according to one or more embodiments may include ZnS. The shell SH may have a thickness of about 0.5 nm or greater and about 3 nm or less. The quantum dot QD-C including the shell SH containing ZnS may exhibit high material stability against UV light. The shell SH may include ZnS which has a higher band gap than a band gap of the core CO, thereby contributing to improvement in efficiency and stability of the quantum dot QD-C.

The shell SH may further include a metal or a non-metal oxide, a semiconductor compound, and/or a (e.g., any suitable) combination thereof. Examples of the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO; a ternary compound such as MgAl₂O₄, CoFe₂O₄, NiFe₂O₄, and/or CoMn₂O₄; or a (e.g., any suitable) combination thereof. Examples of the semiconductor compound may include a Group III-VI semiconductor compound, a Group II-VI semiconductor compound, a Group III-V semiconductor compound, a Group III-VI semiconductor compound, a Group I-III-VI semiconductor compound, a Group IV-VI semiconductor compound, as described in this specification, or a (e.g., any suitable) combination thereof. For example, the semiconductor compound may include ZnSe, ZnTe, ZnSeS, ZnTeS, GaAs, GaP, GaS, GaSe, AgGaS, AgGaS2, GaSb, HgS, HgSe, HgTe, InAs, InP, InGaP, InSb, AlAs, AlP, AlSb, or a (e.g., any suitable) combination thereof.

Each element included in the multi-element compound such as the binary compound and the ternary compound may exist in a particle with an even concentration or uneven concentration. For example, the formula may refer to the type (kind) of elements included in the compound, and the element ratio in the compound may vary.

The shell SH may have a single layer or multiple layers. The shell SH may include a first layer SH1 around (e.g., surrounding) the core CO and a second layer SH2 around (e.g., surrounding) the first layer SH1. The shell SH may have a double-layer structure including the first layer SH1 containing ZnS and the second layer SH2 containing the same or different material as/from that of the first layer SH1. The first layer SH1 and the second layer SH2 may each have a thickness of about 0.5 nm or greater and about 3 nm or less. The thickness of the second layer SH2 may be relatively larger than the thickness of the first layer SH1. For example, the thickness of the first layer SH1 may be about 0.5 nm or greater and about 1 nm or less, and the thickness of the second layer SH2 may be about 1 nm or greater and about 3 nm or less.

The second layer SH2 may include any ionic compound represented by Formula 1 below.

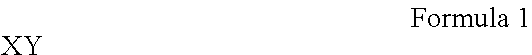

In Formula 1 above, X may refer to a cation, and Y may refer to an anion. For example, X may be a divalent or trivalent cation. X may have an amount of about 10 mass (weight) percent or greater and about 50 mass (weight) percent or less based on 100 mass percent (e.g., wt %) of the total mass included in the second layer SH2. For example, the second layer SH2 may include ZnSe, ZnS, ZnTe, ZnO, ZnMg, ZnMgSe, ZnMgS, ZnMgAl, GaSe, GaTe, GaP, GaAs, GaSb, InAs, InSb, AlP, AlAs, AlSb, MnS, MnSe, MgS, MgSe, or a (e.g., any suitable) combination thereof.

In one or more embodiments, the quantum dot QD-C may further include a ligand. The ligand may eliminate defects, and/or the like, on the core CO and/or the shell SH, and may improve stability of the quantum dot QD-C.

For example, the ligand may include an organic ligand and/or a halogenated metal. The ligand may include at least one of octadecane, octadecene, methanethiol, ethanethiol, propanethiol, butanethiol, pentanethiol, hexanethiol, octanethiol, dodecanethiol, hexadecanethiol, octadecanethiol, benzylthiol, methane amine, ethane amine, propane amine, butyl amine, pentyl amine, hexyl amine, octyl amine, dodecyl amine, hexadecyl amine, octadecyl amine, dimethyl amine, diethyl amine, dipropyl amine, oleyl amine, trioctyl amine, methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid, trimethyl phosphine, methyl diphenyl phosphine, triethyl phosphine, ethyl diphenyl phosphine, trioctyl phosphine, trimethyl phosphine oxide, methyl diphenyl phosphine oxide, triethyl phosphine oxide, ethyl diphenyl phosphine oxide, and/or trioctyl phosphine oxide. However, this is an example, and the ligand may include a suitable ligand material generally available and/or generally utilized in the relevant art, without limitation.

The following description may be applied to one or two quantum dots, other than the quantum dot QD-C according to one or more embodiments described above, among the first to third quantum dots QD-C1, QD-C2, and QD-C3. Hereinafter, for the convenience of description, the one or two quantum dots are referred to as ‘sub-quantum dot’.

The sub-quantum dot may be to emit light of one or more suitable light-emitting wavelengths according to crystal size. The sub-quantum dot may have a diameter of, for example, about 1 nm to about 10 nm.

The sub-quantum dot may be synthesized by a wet chemical process, a metal organic chemical vapor deposition process, a molecular beam epitaxy process, or a similar process. The wet chemical process is a method of mixing an organic solvent and a precursor material to grow quantum dot particle crystals. When the crystals grow, the organic solvent may naturally serve as a dispersant coordinated on a surface of the quantum dot crystal, and may control the growth of the crystals. Therefore, the wet chemical process may control the growth of quantum dot particles more easily than a chemical vapor deposition such as metal organic chemical vapor deposition (MOCVD) or molecular beam epitaxy (MBE), and may cost less.

The sub-quantum dot may include a Group II-VI semiconductor compound; a Group I-II-VI semiconductor compound; a Group II-IV-VI compound; a Group I-II-IV-VI semiconductor compound; a Group III-V semiconductor compound; a Group III-VI semiconductor compound; a Group I-III-VI semiconductor compound; a Group IV-VI semiconductor compound; a Group II-IV-V semiconductor compound; a Group IV element or compound; or a (e.g., any suitable) combination thereof. In this specification, a “Group” refers to a group according to the IUPAC Periodic Table.

Examples of the Group II-VI semiconductor compound may include a binary compound such as ZnS, ZnSe, ZnTe, ZnO, HgS, HgSe, HgTe, MgSe, and/or MgS; a ternary compound such as ZnSeS, ZnSeTe, ZnSTe, HgSeS, HgSeTe, HgSTe, HgZnS, HgZnSe, HgZnTe, MgZnSe, and/or MgZnS; and/or a quaternary compound such as HgZnSeS, HgZnSeTe, and/or HgZnSTe; or a (e.g., any suitable) combination thereof.

The Group II-VI semiconductor compound may further include a Group I metal and/or a Group IV element. The Group I-II-VI compound may be selected from among CuSnS and CuZnS, and the Group II-IV-VI compound may be selected from among ZnSnS, and/or the like. The Group I-II-IV-VI compound may be selected from among a quaternary compound selected from the group consisting of Cu₂ZnSnS₂, Cu₂ZnSnS₄, Cu₂ZnSnSe₄, Ag₂ZnSnS₂, and/or a (e.g., any suitable) mixture thereof.

Examples of the Group III-V semiconductor compound may include a binary compound such as GaN, GaP, GaAs, GaSb, AlN, AlP, AlAs, AlSb, InN, InP, InAs, and/or InSb; a ternary compound such as GaNP, GaNAs, GaNSb, GaPAs, GaPSb, AlNP, AlNAs, AlNSb, AIPAS, AIPSb, InGaP, InNP, InAlP, InNAs, InNSb, InPAs, and/or InPSb; a quaternary compound such as GaAlNP, GaAlNAs, GaAlNSb, GaAlPAs, GaAlPSb, GalnNP, GalnNAs, GalnNSb, GalnPAs, GalnPSb, InAlNP, InAlNAs, InAlNSb, InAlPAs, and/or InAlPSb; or a (e.g., any suitable) combination thereof. The Group III-V semiconductor compound may further include a Group II element.

Examples of the Group III-V semiconductor compound further including a Group II element may include InZnP, InGaZnP, InAlZnP, and/or the like.

Examples of the Group III-VI semiconductor compound may include a binary compound such as GaS, Ga₂S₃, GaSe, Ga₂Se₃, GaTe, InS, InSe, In₂Se₃, and/or InTe; a ternary compound such as InGaS₃ and/or InGaSe₃; and/or a (e.g., any suitable) combination thereof.

Examples of the Group I-III-VI semiconductor compound may include a ternary compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, and/or AgAlO₂; a quaternary compound such as AgInGaS₂, AgInGaSe₂, and/or CuInGaS₂; or a (e.g., any suitable) combination thereof.

Examples of the Group IV-VI semiconductor compound may include a binary compound such as SnS, SnSe, SnTe, PbS, PbSe, and/or PbTe; a ternary compound such as SnSeS, SnSeTe, SnSTe, PbSeS, PbSeTe, PbSTe, SnPbS, SnPbSe, and/or SnPbTe; a quaternary compound such as SnPbSSe, SnPbSeTe, and/or SnPbSTe; or a (e.g., any suitable) combination thereof.

Examples of the Group II-IV-V semiconductor compound may be a ternary compound selected from the group consisting of ZnSnP, ZnSnP₂, ZnSnAs₂, ZnGeP₂, and ZnGeAs₂, and a (e.g., any suitable) mixture thereof.

The Group IV element or compound may include a single-element compound such as Si and/or Ge; a binary compound such as SiC and/or SiGe; or a (e.g., any suitable) combination thereof.

Each element included in the multi-element compound such as the binary compound, the ternary compound, and/or the quaternary compound may exist in a particle with an even concentration or uneven concentration. For example, the formula may refer to the type (kind) of elements included in the compound, and the element ratio in the compound may vary. For example, AgInGaS₂ may refer to AgInₓGa₁₋ₓS₂ (x is a real number of 0 to 1).

The sub-quantum dot may have a single structure including each element with the same concentration throughout the quantum dot, or may have a core-shell double structure. For example, a material included in the core and a material included in the shell may be different from each other.

The shell of the sub-quantum dot may serve as a protection layer that prevents chemical denaturation of the core to maintain semiconductor characteristics, and/or may serve as a charging layer for providing electrophoretic characteristics to the quantum dot. The shell may have a single layer or multiple layers. The core-shell structure may have a concentration gradient in which the concentration of an element existing in the shell decreases (or increases) toward the core.

Examples of the shell of the sub-quantum dot may include a metal or non-metal oxide, a semiconductor compound, and/or a (e.g., any suitable) combination thereof. For the examples of the metal or non-metal oxide, the semiconductor compound, or the combination thereof, the description on the shell SH may be applied equally hereto.

The sub-quantum dot may have a full width of half maximum (FWHM) of about 45 nm or less, for example, about 40 nm or less, or about 30 nm or less in a light-emitting wavelength spectrum, and in this range, color purity or color reproducibility may be improved. In one or more embodiments, because light emitted through this sub-quantum dot is emitted in all directions, the wide viewing angle may be improved. In one or more embodiments, the sub-quantum dot may have a spherical shape, a pyramid shape, a multi-arm shape, or a cubic nanoparticle, nanotube, nanowire, nanofiber, nano plate-like particle shape, and/or the like.

By controlling the size of the sub-quantum dot or controlling the element ratio in the compound constituting the sub-quantum dot, the energy band gap may be controlled or selected, so that light in one or more wavelength ranges may be obtained in a emission layer EML including the sub-quantum dot. Accordingly, by using the sub-quantum dot as described above (using quantum dots with different sizes or differentiating the element ratio in the quantum dot compound), the light-emitting elements ED and ED-a (see, e.g., FIGS. 8A and 8B) emitting light of one or more wavelengths may be achieved. I For example, by controlling the size of the sub-quantum dot or the element ratio in the compound constituting the sub-quantum dot, light of red color, green color, and/or blue color may be selected to be emitted. In one or more embodiments, the sub-quantum dots may be provided such that one or more color light combines to emit white color light.

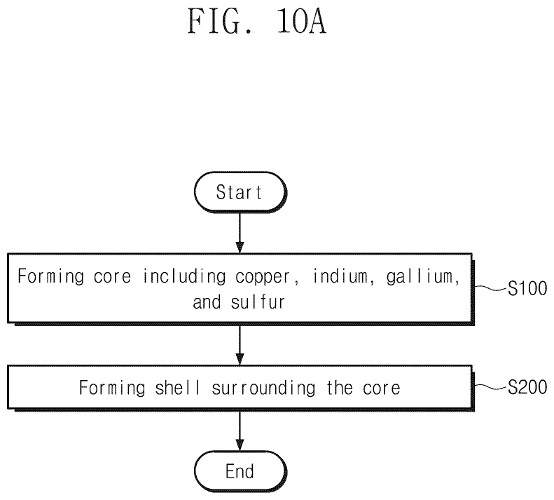

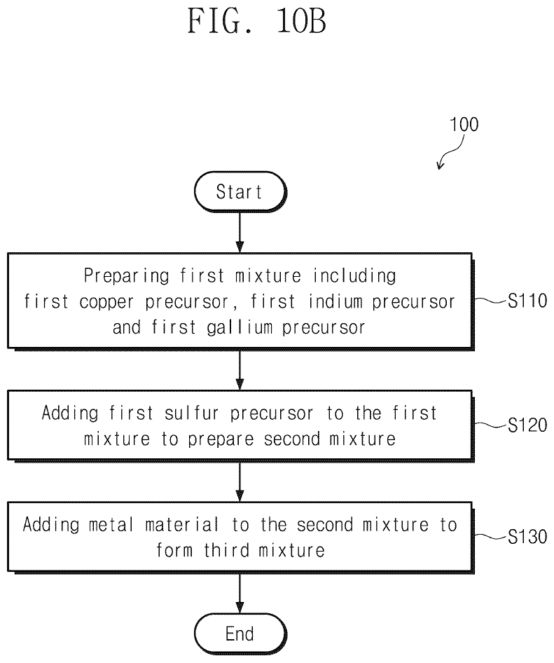

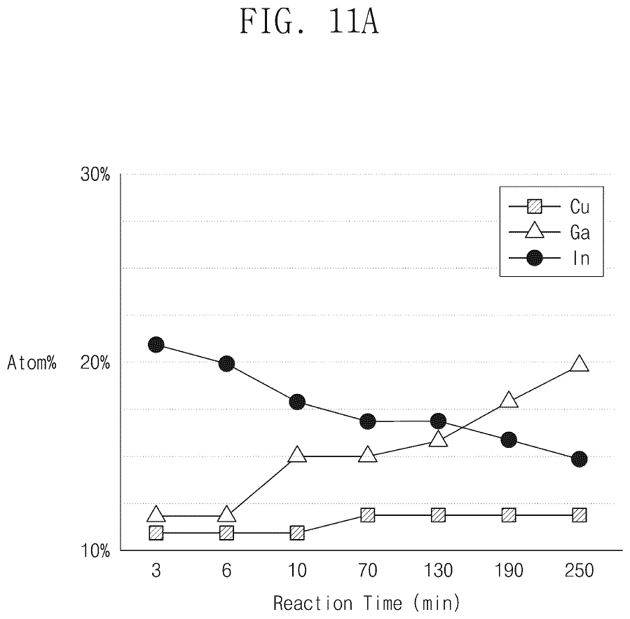

The quantum dot according to one or more embodiments may be manufactured by a method for manufacturing a quantum dot according to one or more embodiments of the present disclosure. FIG. 10A is a flow chart illustrating a method for manufacturing a quantum dot according to one or more embodiments of the present disclosure, and FIG. 10B is a flow chart illustrating a part of the method for manufacturing the quantum dot according to one or more embodiments of the present disclosure. FIG. 10B illustrates forming a core (S100) of the method for manufacturing the quantum dot according to one or more embodiments of the present disclosure.

Hereinafter, in describing with reference to FIGS. 10A and 10B, duplicate content already described with reference to FIGS. 1 to 9 may not be described again, and differences will be mainly described.

Referring to FIG. 10A, the method for manufacturing the quantum dot according to one or more embodiments includes forming a core (S100) containing copper, indium, gallium, and sulfur. The method for manufacturing the quantum dot according to one or more embodiments includes forming a shell (S200) around (e.g., surrounding) the core.

Referring to FIGS. 10A and 10B, in the method for manufacturing the quantum dot according to one or more embodiments, the forming of the core (S100) containing copper, indium, gallium, and sulfur includes preparing a first mixture containing a first copper precursor, a first indium precursor, and a first gallium precursor (S110), adding a first sulfur precursor to the first mixture to form a second mixture (S120), and adding a metal material to the second mixture to form a third mixture (S130).

In this specification, the metal precursor is a material containing a metal and a substance chemically bonded to the metal, where the chemically bonded substance may refer to a substance capable of being easily separated from the metal. For example, the metal precursor may be provided as a type (kind) of salt. The metal of the metal precursor may be a substance included in the quantum dot QD-C according to one or more embodiments.

The copper precursor may include copper powder, copper halide, copper sulfate, copper acetylacetonate, copper hydroxide, copper oxide, copper nitrate, copper carboxylate, an alkylated copper compound, and/or a (e.g., any suitable) combination thereof. For example, the copper precursor may include at least one of copper (I) iodine, copper acetate, or copper nitrate.

The gallium precursor may include gallium powder, gallium halide, gallium sulfate, gallium acetylacetonate, gallium hydroxide, gallium oxide, gallium nitrate, gallium carboxylate, an alkylated gallium compound, and/or a (e.g., any suitable) combination thereof. For example, the gallium precursor may include at least one of gallium nitride, gallium phosphide, gallium (III) chloride, gallium (III) acetylacetonate, gallium (III) bromide, gallium (III) chloride, gallium (III) fluoride, gallium (III) iodide, gallium (III) nitrate hydrate, gallium (III) sulfate, or gallium (III) sulfate hydrate.

The indium precursor may include indium powder, indium halide, indium sulfate, indium acetylacetonate, indium hydroxide, indium oxide, indium nitrate, indium carboxylate, an alkylated indium compound, and/or a (e.g., any suitable) combination thereof. For example, the indium precursor may include at least one of indium (III) acetylacetonate, indium (III) bromide, indium (III) chloride, indium (III) fluoride, indium (III) iodide, indium (III) acetate, trimethyl indium, alkyl indium, aryl indium, indium (III) myristate, indium (III) myristate acetate, or indium (III) di-myristate acetate. The aryl is an aryl group, which refers to any functional group or substituent derived from an aromatic hydrocarbon ring. The aryl group may be a monocyclic aryl group or a polycyclic aryl group. The aryl group may have 6 to 60, 6 to 30, 6 to 20, or 6 to 15 ring-forming carbon atoms. Examples the aryl group may include a phenyl group, a naphthyl group, a fluorenyl group, an anthracenyl group, a phenanthryl group, a biphenyl group, a terphenyl group, a quaterphenyl group, a quinquephenyl group, a sexyphenyl group, a triphenylenyl group, a pyrenyl group, a benzo fluoranthenyl group, a chrysenyl group, and/or the like, but the present disclosure is not limited thereto.

The sulfur precursor may include sulfur powder, sulfur halide, sulfur sulfate, sulfur acetylacetonate, sulfur hydroxide, sulfur oxide, sulfur nitrate, sulfur carboxylate, an alkylated sulfur compound, and/or a (e.g., any suitable) combination thereof. For example, the sulfur precursor may include at least one of sulfur-trioctylphosphine (S-TOP), sulfur-tributylphosphine (S-TBP), sulfur-triphenylphosphine (S-TPP), sulfur-oleylamine (S-oleylamine), sulfur-trioctylamine (S-TOA), sulfur-octadecene (S-ODE), sulfur-diphenylphosphine (S-DPP), sulfur-dodecylamine (S-dodecylamine), octanethiol, dodecanethiol (DDT), octadecanethiol, α-toluenethiol, allyl mercaptan, or bis(trimethylsilyl) sulfide.

The forming of the core (S100) includes the preparing of the first mixture (S110) containing the first copper precursor, the first indium precursor, and the first gallium precursor.

The first mixture includes the first copper precursor, the first indium precursor, and the first gallium precursor. For materials included in the first copper precursor, the first indium precursor, and the first gallium precursor, the descriptions on the copper precursor, the indium precursor, and the gallium precursor, previously described, may be respectively applied thereto. For example, the first copper precursor of the first mixture may include copper iodide. The first gallium precursor may include at least one of gallium iodide, gallium chloride, or gallium acetate. The first indium precursor may include at least one of indium iodide, indium chloride, or indium acetate.

The forming of the core (S100) may further include heating the first mixture at a first temperature after the preparing of the first mixture (S110). The first mixture may be degassed for about 10 minutes at the first temperature. For example, the first temperature may be about 120° C. However, this is an example, and the temperature and duration for degassing the first mixture are not limited thereto.

The forming of the core (S100) includes the adding of the first sulfur precursor to the first mixture to form the second mixture (S120).

The second mixture may be formed by adding the first sulfur precursor to the first mixture. For a material included in the first sulfur precursor, the description on the sulfur precursor previously described may be applied thereto. For example, the first sulfur precursor may include at least one of sulfur-oleylamine, octanethiol, or dedecylthiol in the second compound.

The forming of the core (S100) may further include heating the second mixture from the first temperature to a second temperature after the preparing of the second mixture (S120). The second mixture may be heated from the first temperature to the second temperature, and the core CO (see, e.g., FIG. 9) may be formed at the second temperature. The second mixture may be heated for about 4 hours at the second temperature. For example, the second mixture is heated from the first temperature to a second temperature at which the core forms (e.g., at least about 200° C., e.g., at least about 280° C.) for a suitable duration (e.g., about 4 hours), while additions of the metal material may be performed during the ramp or hold as described herein. However, this is an example, and the temperature and duration for heating the second mixture are not limited thereto.

The forming of the core (S100) includes the adding of the metal material to the second mixture to form the third mixture (S130).

The metal material includes at least one of a second copper precursor, a second indium precursor, a second gallium precursor, or a second sulfur precursor. The metal material may include any one among the second copper precursor, the second indium precursor, the second gallium precursor, and the second sulfur precursor, or any two or more thereof. In one or more embodiments, the metal material may include all of the second copper precursor, the second indium precursor, the second gallium precursor, and the second sulfur precursor. For materials included in the second copper precursor, the second indium precursor, the second gallium precursor, and the second sulfur precursor, the descriptions on the copper precursor, the indium precursor, the gallium precursor, and the sulfur precursor previously described may be respectively applied thereto. For example, the second copper precursor may include copper iodide. The second gallium precursor may include at least one of gallium iodide, gallium chloride, or gallium acetate. The second indium precursor may include at least one of indium iodide, indium chloride, or indium acetate.

The second copper precursor, the second indium precursor, the second gallium precursor, and/or the second sulfur precursor included in the metal material may include the same materials as the first copper precursor, the first indium precursor, and/or the first gallium precursor included in the first compound, and/or the first sulfur precursor included in the second compound, respectively.

The forming of the third mixture (S130) may be performed during the heating of the second mixture from the first temperature to the second temperature. For example, the adding of the metal material to the second mixture may be performed during the heating of the second mixture from the first temperature to the second temperature. For example, while the heating of the second mixture from the first temperature to the second temperature is performed continuously for about 4 hours, the adding of the metal material to the second mixture may be performed temporarily in the middle (e.g., during this process).

In the forming of the third mixture (S130), the adding of the metal material may be repeated n times while the second mixture is heated from the first temperature to the second temperature. The forming of the third mixture (S130) may include adding a first metal material to the second mixture to form a (2-1)-th mixture, . . . , and adding an (n)-th metal material to a (2-(n-1))-th mixture to form a (2-(n))-th mixture. The first to (n)-th metal compound may be the same, or different from each other. n above may be an integer of 1 or greater and 7 or less. For example, n may be an integer of 2 or greater and 5 or less. In one or more embodiments, if the number of repetitions n is 3, the forming of the third mixture (S130) may include adding the first metal material to the second mixture to form the (2-1)-th mixture, adding the second metal material to the (2-1)-th mixture to form the (2-2)-th mixture, and adding the third metal material to the (2-2)-th mixture to form the (2-3)-th mixture.

In the forming of the third mixture (S130), the adding of the metal material may be repeated n times at a first cycle while the second mixture is heated from the first temperature to the second temperature. A cycle of the first cycle may be about 30 minutes or greater and about 2 hours or less. For example, the first cycle may be about 1 hour.

In the forming of the third mixture (S130), an atomic percentage of the indium may decrease with heating time, and an atomic percentage of the gallium may increase with heating time. Accordingly, the core CO (see, e.g., FIG. 9), manufactured by the method for manufacturing the quantum dot according to one or more embodiments of the present disclosure, may have a concentration gradient in which the concentration of the indium element increases toward the center point of the core, and may have a concentration gradient in which the concentration of the gallium element decreases toward the center point of the core.

Each of the first mixture, the second mixture, and the third mixture may further include a solvent in which a precursor is dissolved. Each of the first mixture, the second mixture, and the third mixture may further include at least one of oleylamine, 1-octadecene, octadecane, methanethiol, ethanethiol, propanethiol, butanethiol, pentanethiol, hexanethiol, octanethiol, hexadecanethiol, benzylthiol, methane amine, ethane amine, propane amine, butylamine, pentylamine, hexylamine, octylamine, dodecylamine, hexadecylamine, octadecylamine, dimethylamine, diethylamine, dipropylamine, trioctylamine, methanoic acid, ethanoic acid, propanoic acid, buthanoic acid, pentanoic acid, hexanoic acid, heptanoic acid, octanoic acid, dodecanoic acid, hexadecanoic acid, octadecanoic acid, oleic acid, benzoic acid, trimethyl phosphine, methyldiphenyl phosphine, triethyl phosphine, ethyldiphenyl phosphine, trioctyl phosphine, trimethyl phosphine oxide, methyldiphenyl phosphine oxide, triethyl phosphine oxide, ethyldiphenyl phosphine oxide, or trioctyl phosphine oxide.

The method for manufacturing the quantum dot according to one or more embodiments may further include cooling and refining after the forming of the third mixture (S130). For example, the cooling and the refining may be performed at room temperature. The refining may be performed by using chloroform, ethanol, acetone, or a (e.g., any suitable) combination thereof. However, the present disclosure is not limited thereto, and the refining of the core may not be provided in the method for manufacturing the quantum dot depending of the process conditions.

The first copper precursor, the first indium precursor, the first gallium precursor, the first sulfur precursor, and the metal material, added according to the previously-described steps, may react to form the core CO (see, e.g., FIG. 9).

A method for manufacturing a quantum dot of the related art may include preparing a copper precursor, a gallium precursor, and an indium precursor as one mixture, providing a sulfur precursor to the mixture, and heating the mixture to synthesize a core. The quantum dot manufactured therefrom has a full width of half maximum greater than about 60 nm and/or a quantum yield less than about 85%.

Unlike this, the method for manufacturing the quantum dot according to one or more embodiments may include further adding at least one of a copper precursor, a gallium precursor, an indium precursor, or a sulfur precursor during the step (e.g., act or task) of synthesizing the core by heating, thereby manufacturing an excellent or suitable quantum dot with particle uniformity. Therefore, the method for manufacturing the quantum dot according to one or more embodiments may have excellent or suitable processibility. The quantum dot manufactured by the method for manufacturing the quantum dot according to one or more embodiments may have a full width of half maximum of about 60 nm or less, and have a quantum yield of about 85% or greater.

After the forming of the core (S100), the forming of the shell (S200) around (e.g., surrounding) the core may be performed.

In the forming of the shell (S200), a metal precursor may be added to a solution in which the refined core is dispersed in a solvent, and then reacted and agitated. The precursor may be a precursor of the metal constituting the shell SH (see, e.g., FIG. 9). Accordingly, the core and the precursor react to each other to form a shell around (e.g., surrounding) the core.

When the shell SH (see, e.g., FIG. 9) has a multi-layer structure, the forming of the shell (S200) may be continuously performed two or more times. For example, the forming of the shell (S200) may include forming a first layer around (e.g., surrounding) the core, and forming a second layer around (e.g., surrounding) the first shell. At this time, any one among the type (kind), the amount of the precursor, and/or the reaction temperature condition for forming the multi-layer structure of the shell may be different, but the present disclosure is not limited thereto.

In one or more embodiments, the forming of the shell (S200) may include providing a zinc precursor and a third sulfur precursor to the core and forming the shell at a temperature of about 200° C. or higher.

The core, the zinc precursor, and the third sulfur precursor may be provided in a flask. Before the core, the zinc precursor, and the third sulfur precursor are provided, the flask may include vacuum-treated trioctylamine. The core, the zinc precursor, and the third sulfur precursor may react to form a shell around (e.g., surrounding) the core. The temperature of about 200° C. or higher may be a temperature appropriate or suitable for the formation of the quantum dot including the core and the shell because reactivity of the core, zinc precursor, and the third sulfur precursor is high. For example, the reaction in the forming of the shell may be performed at a temperature of about 250° C. for about 20 minutes.

The third sulfur precursor may be the same as, or different from each of the first and second sulfur precursors. For the third sulfur precursor, the description on the sulfur precursor previously described may be applied thereto. For example, the second sulfur precursor may include at least one of sulfur-trioctylphosphine (S-TOP), sulfur-tributylphosphine (S-TBP), sulfur-triphenylphosphine (S-TPP), sulfur-oleylamine (S-oleylamine), sulfur-trioctylamine (S-TOA), sulfur-octadecene (S-ODE), sulfur-diphenylphosphine (S-DPP), sulfur-dodecylamine, octanethiol, dodecanethiol, octadecanethiol, α-toluenethiol, allyl mercaptan, or bis(trimethylsilyl) sulfide.

The method for manufacturing the quantum dot according to one or more embodiments may further include ashing the manufactured quantum dot after the forming of the shell (S200). The ashing of the quantum dot may be a step (e.g., act or task) of performing a reaction by adding trioctylphosphine. However, the present disclosure is not limited thereto.

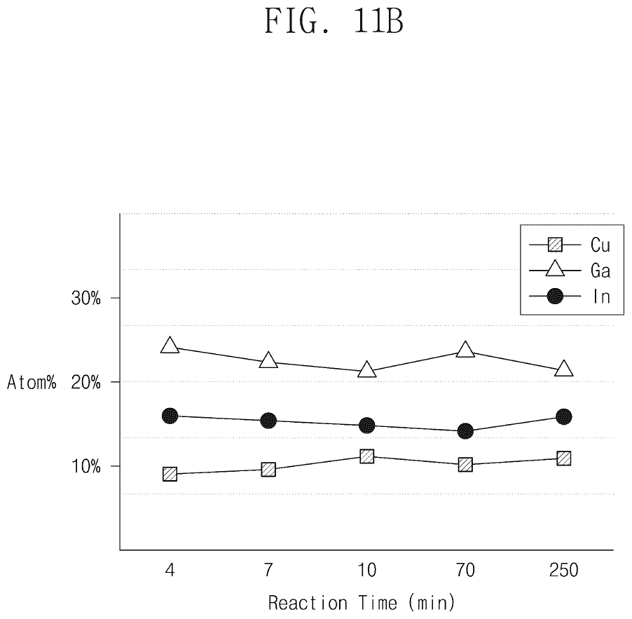

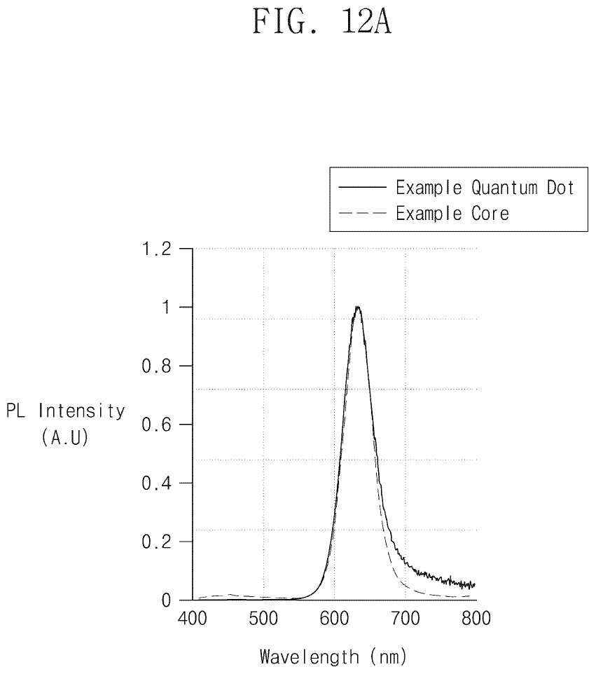

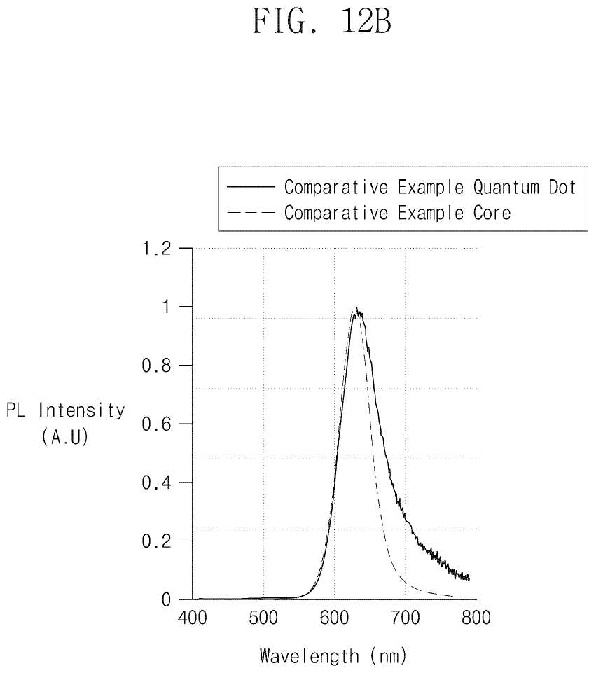

Hereinafter, referring to FIGS. 11A, 11B, 12A, and 12B, and an example, the quantum dot according to one or more embodiments of the present disclosure and the method for manufacturing the quantum dot will be described in more detail. In addition, the following example is intended to help understanding of the present disclosure, and the scope of the present disclosure is not limited thereto.

### MANUFACTURING METHOD FOR EXAMPLE AND COMPARATIVE EXAMPLE

### 1) Method for Manufacturing Example Quantum Dot

A first mixture was provided into a first flask, and degassing was performed at about 120° C. for about 10 minutes. In the first mixture, a first copper precursor, a first indium precursor, a first gallium precursor, oleylamine, and octadecene were included. A second mixture was provided into a second flask. In the second mixture, a first sulfur precursor and dodecanethiol were included. The second mixture was provided to the first flask, and heated from about 120° C. to a high (e.g., second) temperature of about 280° C. or higher. During the heating, a metal material was added to the first flask at about 1 hour interval to form a third mixture. In the metal material, a second copper precursor, a second indium precursor, a second gallium precursor, and a second sulfur precursor were included. After this, the third mixture was cooled and refined to obtain an example core.

According to the example, the first and second copper precursors included copper iodide, the first and second indium precursors included indium iodide, the first and second gallium precursors included gallium iodide, and the first and second sulfur precursors included sulfur-oleylamine.

Vacuum-treated trioctylamine was prepared in a third flask, and the example core, a zinc precursor, and a third sulfur precursor were injected thereto. Heating at about 250° C. and reaction for about 20 minutes were performed to obtain an example quantum dot including the example core containing the CIGS compound, and a shell containing ZnS.

### 2) Method for Manufacturing Comparative Example Quantum Dot

A comparative example quantum dot was prepared by a manufacturing method in the following, and the method for manufacturing the comparative example quantum dot does not include the step (e.g., act or task) of adding a metal material, unlike the method for manufacturing the example quantum dot.

A fourth mixture was provided into a fourth flask, and degassing was performed at about 120° C. for about 10 minutes. In the fourth mixture, a first copper precursor, a first indium precursor, a first gallium precursor, oleylamine, and octadecene were included. In a fifth mixture, a first sulfur precursor and dodecanethiol were included. The fifth mixture was provided to the fourth flask, and heated from about 120° C. to a high (e.g., second) temperature of about 280° C. or higher for about 4 hours. After this, the fifth mixture was cooled and refined to obtain a comparative example core.

According to the comparative example, the first copper precursor included copper iodide, the first indium precursor included indium iodide, the first gallium precursor included gallium iodide, and the first sulfur precursor included sulfur-oleylamine.

Vacuum-treated trioctylamine was prepared in a fifth flask, and the comparative example core, a zinc precursor, and a third sulfur precursor were injected thereto. Heating at about 250° C. and reaction for about 20 minutes were performed to obtain a comparative example quantum dot including the comparative example core containing the CIGS compound, and a shell containing ZnS.

### Evaluation on Characteristics of Example and Comparative Example

FIG. 11A is a line graph showing changes in core composition over time, according to one or more embodiments of the present disclosure. FIG. 11B is a graph showing changes in core composition over time according to a comparative example. FIG. 11A shows the compositions of the example core by time while the second mixture was heated from about 120° C. to a high temperature of about 280° C. or higher. FIG. 11B shows the compositions of the comparative example core by time while the fifth mixture was heated from about 120° C. to a high temperature of about 280° C. or higher. In FIGS. 11A and 11B, the core composition was analyzed by an inductively coupled plasma (ICP), and the composition was expressed in atomic percentage (at %), and the composition ratio of the sulfur element for the CIGS compound was omitted.

Referring to FIG. 11A, it can be seen that the composition ratio of indium tends to decrease and the composition of gallium tends to increase while the example core is formed. In the example core, it can be seen that the composition of indium has a relatively larger value than the composition of gallium for the reaction time up to about 130 minutes, but on the contrary, from about 130 minutes onwards, the composition of indium has a relatively smaller value than the composition of gallium. Accordingly, it can be seen that the example core has a concentration gradient in which the concentration of indium increases toward the center point of the core, and has a concentration gradient in which the concentration of gallium element increases toward the outer surface of the core. In contrast, referring to FIG. 11B, it can be seen that, in the comparative example core, the composition of indium has consistently smaller values than the composition of gallium for the entire reaction time. Therefore, the comparative example core may not have a relative concentration gradient for the indium element and the gallium element.

FIG. 12A is a graph showing luminescence intensity according to wavelength for a core and a quantum dot according to one or more embodiments of the present disclosure. FIG. 12B is a graph showing luminescence intensity according to wavelength for a core and a quantum dot according to a comparative example. FIGS. 12A and 12B are graphs showing photoluminescence (PL) intensity according to wavelength of the core and quantum dot according to the example and comparative example, respectively, and PL was expressed as a normalized value. In FIGS. 12A and 12B, the maximum value of luminescence intensity was set as 1, and a relative luminescence intensity according to wavelength was expressed as A. U.

Table 1 shows a maximum luminescence wavelength, a full width of half maximum (FWHM), a tail, and a quantum yield for the core and quantum dot according to each of the example and comparative example on the basis of the graphs in FIGS. 12A and 12B. In Table 1, the maximum luminescence wavelength indicates a central emission wavelength, and the tail refers to a value satisfying Equation 1. The quantum yield was measured through the measurement of absorbance according to wavelength.

$$Tail = \vert {T}_{1} - {T}_{2} \vert \qquad Equation 1$$

In Equation 1 above, “Tail” is an absolute value of T₁ minus T₂. T₁ and T₂ each refers to a difference between the wavelength with a luminescence intensity of about 0.1 and the maximum luminescence wavelength. That is, “Tail” is reported as an absolute value; lower values indicate higher particle uniformity. For example, T₁ may refer to a difference between a large value among the wavelength values with a luminescence intensity value of about 0.1 and the maximum luminescence wavelength, and T₂ may refer to a difference between a small value among the wavelength values with a luminescence intensity value of about 0.1 and the maximum luminescence wavelength. As the tail is closer to 0, the PL graph has high left-right symmetry, and the uniformity of particles is considered suitable or excellent.

TABLE 1

| | Maximum | | | |
|---|---|---|---|---|
| | luminescence | | | |
| | wavelength | FWHM | Tail | Quantum yield |
| | (nm) | (nm) | (nm) | (%) |
| Example core | 635 | 47 | 6 | — |
| Example | 632 | 50 | 47 | 95 |
| quantum dot | | | | |
| Comparative | 630 | 50 | 6 | — |
| Example core | | | | |
| Comparative | 631 | 67 | 81 | 81 |
| Example | | | | |
| quantum dot | | | | |

Referring to FIGS. 12A, 12B, and Table 1, it can be seen that the example quantum dot has lower FWHM and tail values and higher quantum yield than the comparative example quantum dot. Unlike the comparative example core, the example core has a concentration gradient in which the concentration of indium increases toward the center point of the core, and the concentration of gallium increases toward the outer surface of the core. In addition, unlike the step (e.g., act or task) of forming the comparative example core, in the step (e.g., act or task) of forming the example core, the atomic percentage of indium tends to decrease according to heating time, and the atomic percentage of gallium tends to increase according to heating time, and a step (e.g., act or task) of adding a metal material is included. Accordingly, it can be seen that the example quantum dot, compared to the comparative example quantum dot, emits light of high color purity for a wavelength range of about 500 nm to about 650 nm, exhibits excellent or suitable uniformity, and has high luminance efficiency. When comparing the FWHM and tail results of the comparative example core to the FWHM and tail results of the comparative example quantum dot, it can be seen that it is difficult for the core containing the CIGS compound of the comparative example to provide stability for the shell containing ZnS. In contrast, even though the example quantum dot includes the core containing the CIGS compound and the shell containing ZnS, the core has a relative concentration gradient of indium and gallium in the core, and the step (e.g., act or task) of adding a metal material is included in the forming of the core, thereby achieving high quantum yield with a narrow FWHM and tail.

Accordingly, as previously described, the example core was formed by varying the concentrations of the CIGS throughout the manufacturing process to create a core having concentration gradients of, for example, indium and gallium. Accordingly, it can be seen that the method for manufacturing the example quantum dot, including a step (e.g., act or task) of providing the first mixture containing the copper precursor, a gallium precursor, and an indium precursor as one mixture at certain concentrations, and a step (e.g., act or task) of providing the second mixture containing a second copper precursor, a second indium precursor, and a second gallium precursor at a different concentrations than in the first mixture, after providing the sulfur precursor to the first mixture, may exhibit excellent or suitable processibility. It can be seen that the quantum dot, manufactured by the method for manufacturing the quantum dot according to one or more embodiments, may be to emit light of high color purity, and may have excellent or suitable uniformity.

It can be seen that the method for manufacturing the quantum dot according to one or more embodiments, including the step (e.g., act or task) of adding the metal material containing at least one of the second copper precursor, the second indium precursor, the second gallium precursor, or the second sulfur precursor to a mixture including the first copper precursor, the first indium precursor, the first gallium precursor, and the first sulfur precursor, may exhibit excellent or suitable processibility. It can be seen that the quantum dot, manufactured by the method for manufacturing the quantum dot according to one or more embodiments, may be to emit light of high color purity, and have excellent or suitable uniformity. It can be seen that the quantum dot, manufactured by the method for manufacturing the quantum dot according to one or more embodiments, may be to emit light with a narrow FWHM, and have excellent or suitable light-emitting efficiency. An electronic apparatus including the quantum dot according to one or more embodiments may also have excellent or suitable display quality and excellent or suitable reliability.

The present disclosure provides a method for manufacturing a quantum dot which exhibits excellent or suitable processibility.

The present disclosure also provides a quantum dot which exhibits excellent or suitable efficiency, and an electronic apparatus including the same.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within +30%, 20%, 10%, 5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The quantum dot, display device, electronic apparatus, device for manufacturing the quantum dot, display device, and/or electronic apparatus, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like.

Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A method comprising:
forming a core comprising copper, indium, gallium, and sulfur, and
forming a shell around the core,
wherein the forming of the core comprises:
preparing a first mixture comprising a first copper precursor, a first indium precursor, and a first gallium precursor,
adding a first sulfur precursor to the first mixture to form a second mixture, and
adding a metal material to the second mixture to form a third mixture,
wherein the metal material comprises at least one of a second copper precursor, a second indium precursor, a second gallium precursor, or a second sulfur precursor, and
wherein the method is a method for manufacturing a quantum dot.

2. The method of claim 1, further comprising heating the first mixture at a first temperature after the preparing of the first mixture.

3. The method of claim 1, further comprising heating the second mixture from a first temperature to a second temperature after the forming of the second mixture.

4. The method of claim 3, wherein the forming of the third mixture is performed during the heating of the second mixture from the first temperature to the second temperature.

5. The method of claim 4, wherein, in the forming of the third mixture,
an atomic percentage of the indium decreases with the heating time, and
an atomic percentage of the gallium increases with the heating time.

6. The method of claim 1, wherein the metal material comprises the second copper precursor, the second indium precursor, the second gallium precursor, and the second sulfur precursor.

7. The method of claim 1, wherein the forming of the third mixture comprises the adding of the metal material n times, and n is an integer from 1 to 7.

8. The method of claim 7, wherein n is an integer from 2 to 5.

9. The method of claim 7, wherein
the adding of the metal material n times comprises a first cycle, and
the first cycle is from 30 minutes to 2 hours.

10. The method of claim 1, wherein
the first and second copper precursors each independently comprises copper iodide,
the first and second indium precursors each independently comprises at least one of indium iodide, indium chloride, or indium acetate,
the first and second gallium precursors each independently comprises at least one of gallium iodide, gallium chloride, or gallium acetate, and
the first and second sulfur precursors each independently comprises at least one of sulfur-oleylamine, octanethiol, or dodecanethiol.

11. A quantum dot comprising:
a core comprising copper, indium, gallium, and sulfur; and
a shell around the core,
wherein the core comprises a first portion having a center point and a second portion between the first portion and the shell,
wherein an atomic percentage of the indium in the first portion is greater than an atomic percentage of the indium in the second portion, and
wherein an atomic percentage of the gallium in the first portion is less than an atomic percentage of the gallium in the second portion.

12. The quantum dot of claim 11, wherein the quantum dot has a full width of half maximum of 60 nm or less.

13. The quantum dot of claim 11, wherein a central emission wavelength of the quantum dot is in a wavelength range of 500 nm to 650 nm.

14. The quantum dot of claim 11, wherein, based on 100 wt % of a total mass of the core,
the copper has an amount of 5 wt % to 20 wt %,
the indium has an amount of 10 wt % to 30 wt %,
the gallium has an amount of 10 wt % to 50 wt %, and
the sulfur has an amount of 40 wt % to 60 wt %.

15. The quantum dot of claim 11, wherein the shell comprises ZnS.

16. The quantum dot of claim 11, wherein
the shell comprises a first layer around the core, and a second layer around the first layer, and
the first layer comprises ZnS.

17. The quantum dot of claim 16, wherein the second layer comprises at least one of ZnSe, ZnS, ZnTe, ZnO, ZnMg, ZnMgSe, ZnMgS, ZnMgAl, GaSe, GaTe, GaP, GaAs, GaSb, InAs, InSb, AlP, AlAs, AlSb, MnS, MnSe, MgS, or MgSe.

18. The quantum dot of claim 16, wherein a thickness of the second layer is larger than a thickness of the first layer.

19. An electronic apparatus comprising:
a display module comprising a light-emitting element configured to emit source light; and
an optical layer on the display module, the optical layer being configured to transmit the source light or convert a wavelength of the source light,
wherein the light-emitting element or the optical layer comprises a quantum dot, and wherein the quantum dot comprises:
a core comprising copper, indium, gallium, and sulfur, and
a shell around the core,
wherein the core comprises a first portion having a center point, and a second portion between the first portion and the shell,
wherein a weight percentage of the indium in the first portion is greater than a weight percentage of the indium in the second portion, and
wherein a weight percentage of the gallium in the first portion is less than a weight percentage of the gallium in the second portion.

20. The electronic apparatus of claim 19, further comprising:
a window member on the optical layer; and
a housing under the display module, and coupled to the window member to accommodate the display module and the optical layer.
